(19) United States
(12) Patent Application Publication
(10) Pub. No.: US 2013/0026720 A1
(43) Pub. Date: Jan. 31, 2013

(54) ELECTROSTATIC CHUCK

(71) Applicants: Hiroaki Hori, Fukuoka-ken (JP); Shunpei Kondo, Fukuoka-ken (JP); Yuki Anai, Fukuoka-ken (JP); Ikuo Itakura, Fukuoka-ken (JP); Takeshi Uchimura, Fukuoka-ken (JP); Kazuki Anada, Fukuoka-ken (JP)

(72) Inventors: Hiroaki Hori, Fukuoka-ken (JP); Shunpei Kondo, Fukuoka-ken (JP); Yuki Anai, Fukuoka-ken (JP); Ikuo Itakura, Fukuoka-ken (JP); Takeshi Uchimura, Fukuoka-ken (JP); Kazuki Anada, Fukuoka-ken (JP)

(73) Assignee: TOTO LTD., KITAKYUSHU-SHI, FUKUOKA (JP)

(21) Appl. No.: 13/635,757

(22) PCT Filed: Mar. 23, 2011
(86) PCT No.: PCT/JP2011/057039

§ 371 Date: Oct. 4, 2012

(30) Foreign Application Priority Data
Mar. 24, 2010 (JP) 2010-068982
Mar. 18, 2011 (JP) 2011-061738

(51) Int. Cl. H01L 21/683

(52) U.S. Cl. 279/128

(57) ABSTRACT

An electrostatic chuck comprises: a ceramic plate provided with recesses on a major surface and provided with an electrode in an inner part of the ceramic plate; a temperature regulating plate bonded to the major surface of the ceramic plate; a first bonding agent provided between the ceramic plate and the temperature regulating plate; and a heater provided in the each of the recesses of the ceramic plate. The first bonding agent has a first major agent including an organic material, a first amorphous filler including an inorganic material, and a first spherical filler including an inorganic material. The first amorphous filler and the first spherical filler are dispersion-compounded into the first major agent. The first major agent, the first amorphous filler, and the first spherical filler are made of an electrically insulating material. An average diameter of the first spherical filler is greater than a maximum value of a minor axis of the first amorphous filler. A thickness of the first bonding agent is greater than or equal to the average diameter of the first spherical filler. A width of the each of the recesses is greater than a width of the heater, and a depth of the each of the recesses is greater than a thickness of the heater. The heater is adhered within the each of the recesses by a second bonding agent. A first distance between a major surface of the heater on the side of the temperature regulating plate and a major surface of the temperature regulating plate is greater than a second distance between the major surface between the recesses of the ceramic plate and the major surface of the temperature regulating plate.

### TECHNICAL FIELD

The invention relates to an electrostatic chuck.

### BACKGROUND ART

Electrostatic chucks are used in processes to treat processing target substrates within a vacuum chamber as means for clamping a processing target substrate. In recent years, processes that use high density plasma for the purpose of reducing tact time have become common. Therefore, methods for efficiently removing thermal flux from the high density plasma that inflows to the processing target substrate to outside the electrostatic chuck are required.

For example, a structure is disclosed in which a thermal regulator is bonded by a bonding agent to the bottom side of an electrostatic chuck (for example, see Patent Literature 1). In this structure, a ceramic plate with an electrode is adhered by a rubber, or the like, bonding agent to the top of a metal base substrate of a conductor. Thermal flux that has flowed into the processing target substrate passes through the electrostatic chuck and is conducted to the thermal regulator in which a cooling medium is circulated, where it is exhausted outside the electrostatic chuck by the cooling medium.

However, the thermal conductivity of the bonding agent configured of resin is one to two digits lower compared to the thermal conductivity of the metal base substrate and the ceramic plate. Accordingly, the bonding agent can become an impediment to heat. Therefore, the bonding agent needs to be as thin as possible for the heat to efficiently exhaust. However, thinning the bonding agent can lead to the inability to mitigate deviance between the metal base substrate and the ceramic plate generated by either a temperature difference between the metal base substrate and the ceramic plate or by a difference in the thermal expansion coefficient between the metal base substrate and the ceramic plate due to the bonding agent thereby reducing the adhesive force thereof. In contrast to this, a structure is proposed in which a thermally conductive filler is blended and dispersed into the bonding agent to raise the thermal conductivity of the bonding agent (for example, see Patent Literature 2).

Furthermore, electrostatic chucks that can rapidly change the temperature of a processing target substrate during processing have recently been in demand. To address this, an example is disclosed of an electrostatic chuck that, for example, interposes a plate shaped heater between thick ceramic plates and bonds these to the metal base substrate (for example, see Patent Literature 3).

### CITATION LIST

### Patent Literature

### [PLT 1]

JP 63-283037 A (Kokai)

### [PLT 2]

JP 02-027748 A (Kokai)

### [PLT 3]

JP 2005-347449 A (Kokai)

### SUMMARY OF INVENTION

### Technical Problem

However, interposing a heater between thick ceramic plates lengthens the distance from the processing target substrate to the metal base substrate (hereinafter referred to as temperature regulating plate) and increases the number of bonding agent layers thereby lowering cooling performance. Further, arranging thick ceramic plates above and below a heater increases the thermal capacity of the electrostatic chuck which also worsens response when heating.

Resolving these types of problems requires reducing the thickness of the ceramic plates and the number of bonding agent layers. However, when interposing the heater between the thin ceramic plate and the temperature regulating plate and then adhering these by a single layer of bonding agent in which the thermally conductive filler has been blended and dispersed, the adhering pressure concentrates on the ceramic plate via the heater and cracks may occur in the ceramic plate.

The problem of the invention is to provide an electrostatic chuck that can rapidly heat and cool a processing target substrate while suppressing crack generation in the ceramic plate.

### Solution to Problem

The first invention relates to an electrostatic chuck that includes a ceramic plate provided with recesses on a major surface provided with an electrode in an inner part of the ceramic plate, a temperature regulating plate bonded to the major surface of the ceramic plate, a first bonding agent provided between the ceramic plate and the temperature regulating plate, and a heater provided in the each of recesses of the ceramic plate, wherein the first bonding agent has a first major agent that includes an organic material, a first amorphous filler that includes an inorganic material, and a first spherical filler that includes an inorganic material; the first amorphous filler and the first spherical filler are dispersion-compounded into the first major agent; the first major agent, the first amorphous filler, and the first spherical filler are made of an electrically insulating material; an average diameter of the first spherical filler is greater than a maximum value of an entire minor axis of the first amorphous filler; a thickness of the first bonding agent is greater than or equal to the average diameter of the first spherical filler; a width of the each of the recesses is wider than a width of the heater, and a depth of the each of the recesses is greater than the thickness of the heater; the heater is adhered within the each of the recesses by a second bonding agent; and a first distance between a major surface of the heater on the side of the temperature regulating and a major surface of the temperature regulating plate is greater than a second distance between the major surface between the recesses of the ceramic plates and the major surface of the temperature regulating plate.

Electrical insulating properties can be secured around the heater by having the temperature regulating plate oppose the ceramic plate where the heater is formed and integrate these by adhering with the first bonding agent.

Further, because the first spherical filler and the first amorphous filler are inorganic materials, the respective sizes thereof (for example, the diameter) are easily controlled. Therefore, blending and dispersing of the first bonding agent with the first major agent is easily done. Because the first major agent of the first bonding agent, the first amorphous filler, and the first spherical filler are electrically insulating materials, the electrical insulating properties around the electrode can be secured.

Further, the average diameter of the first spherical filler is greater than the maximum value of entire minor axis of the first amorphous filler. Therefore, the thickness of the first bonding agent can be controlled to greater than or equal to the average diameter of the average diameter of the first spherical filler. By this, crack generation in the ceramic plate can be prevented at the time of hot press curing of the first bonding agent without applying local stress to the ceramic plate by the amorphous filler.

Further, because the first distance between the major surface of the temperature regulating plate side of the heater and the major surface of the temperature regulating plate is longer than the second distance between the major surfaces between the recesses of the ceramic plate and the major surface of the temperature regulating plate, stress becomes more difficult to conduct at the time of hot press curing to the heater by the spherical filler. Therefore, crack generation in the ceramic plate can be prevented without the pressure at the time of hot press curing being conducted to the thin ceramic plate in the recesses via the heater. Further, because the first bonding agent and the second bonding agent reside above and below the heater, the stress due to the heater is difficult to transfer to the ceramic plate even if the heater rapidly expands and contracts. The result is that crack generation in the ceramic plate is suppressed.

The second invention, according to the first invention, is characterized in that the average diameter of the first spherical fillers is 10 μm more than or equal to the maximum value of the minor axis of the amorphous filler.

When the average diameter of the first spherical filler is 10 μm more than or equal to the maximum value of the minor axis of the first amorphous filler, the thickness of the first bonding agent can be controlled by the diameter of the first spherical filler and not by the size of the first amorphous filler at the time of hot press curing the first bonding agent. In other words, at the time of hot press curing, local stress on the ceramic plate is difficult to be applied by the first amorphous filler. By this, crack generation in the ceramic plate can be prevented.

Further, when the variation in the flatness and thickness of the ceramic plates positioned above and below the first bonding agent is not more than 10 μm (for example, 5 μm), the variation in the surface roughness and thickness of the ceramic plate can be absorbed (mitigated) by the first bonding agent by making the average diameter of the first spherical filler to be 10 μm greater than or equal to the maximum value of the minor axis of the first amorphous filler here.

The third invention, according to the first invention, is characterized in that the volume concentration (vol %) of the first spherical filler is more than 0.025 vol % and less than 42.0 vol % relative to the volume of the first bonding agent in which the first amorphous filler is contained.

When the volume concentration (vol %) of the first spherical filler is more than 0.025 vol % relative to the volume of the first bonding agent in which the first amorphous filler is contained, dispersion within the first bonding agent of the first spherical filler is favorable. In other words, the first spherical filler can be diffused evenly in the first bonding agent. By this, the thickness of the first bonding agent can be greater than or equal to the first spherical filler average diameter. Therefore, local stress on the ceramic plate is difficult to be applied by the first amorphous filler when hot press curing the first bonding agent. The result is that crack generation in the ceramic plate can be suppressed.

Further, by making the volume concentration (vol %) thereof to be less than 42.0 vol %, the first spherical filler can be sufficiently stirred into the first bonding agent in which the first amorphous filler is contained. In other words, as long as the volume concentration (vol %) is less than 42.0 vol %, dispersion of the first spherical filler will be uniform within the first bonding agent in which the first amorphous filler is contained.

The fourth invention, according to the first invention, is characterized in that a material for the first major agent of the first bonding agent and a material for the second major agent of the second bonding agent is one of a silicon resin, an epoxy resin, or a fluororesin.

The characteristics of the major agents after the major agents are cured can be appropriately selected by changing the properties of the major agents of the first bonding agent and the second bonding agent. For example, if flexibility is desired in either the first or the second bonding agent after curing, then a silicon resin or a fluororesin with a comparatively low hardness is used. If rigidity is desired in either the first or the second bonding agent after curing, then an epoxy resin with a comparatively high hardness is used. If plasma durability is desired in either the first or the second bonding agent after curing, then a fluororesin is used.

The fifth invention, according to the first invention, is characterized in that a thermal conductivity of the first spherical filler and a thermal conductivity of the first amorphous filler are higher than the thermal conductivity of the first major agent of the first bonding agent.

Because the thermal conductivity of the first spherical filler and the first amorphous filler is higher than that of the first major agent of the first bonding agent, the thermal conductivity of the first bonding agent is greater than that of the bonding agent of the major agent elemental substance and thus cooling performance is improved.

The sixth invention, according to the first invention, is characterized in that the material of the first spherical filler and the material of the first amorphous filler are different.

The purpose of adding the first spherical filler to the first bonding agent is to provide uniformity in the thickness of the first bonding agent and for dispersing the stress applied to the ceramic plate. The purpose of adding the first amorphous filler to the first bonding agent is to improve the thermal conductivity of the first bonding agent and to provide uniformity in the thermal conductivity.

In this manner, selecting a more favored material that matches these purposes allows a better performance to be obtained.

The seventh invention, according to the fifth invention, is characterized in that the thermal conductivity of the first spherical filler is lower than the thermal conductivity of the first amorphous filler.

For example, when the first spherical filler contacts the major surface of the ceramic plate, the difference between the thermal conductivity of this contact portion is lower than that of the other portions. By this, uniformity can be provided in the in-plane temperature distribution of the ceramic plate.

The eighth invention, according to the seventh invention, is characterized in that the thermal conductivity of the first spherical filler is less than or equal to the thermal conductivity of a blended material of the first amorphous filler and the first major agent.

By making the thermal conductivity of the first spherical filler to be less than or equal to the thermal conductivity of the blended material of the first amorphous filler and the first major agent, the thermal conductivity within the first bonding agent becomes further constant, and the generation of a singular point of temperature known as a hot spot or a cold spot within the first bonding agent can be suppressed at the time of thermal conduction.

The ninth invention, according to the eighth invention, is characterized in that the thermal conductivity of the first spherical filler is in a range not less than 0.4 times and not more than 1.0 times the thermal conductivity of a blended material of the first amorphous filler and the first major agent.

Making the thermal conductivity of the first spherical filler to be in a range not less than 0.4 times and not more than 1.0 times the thermal conductivity of a blended material of the first amorphous filler and the first major agent, enables the thermal conductivity within the first bonding agent to be more uniform. As a result, the generation of a singular point of temperature known as a hot spot or a cold spot within the first bonding agent can be suppressed at the time of thermal conduction.

When the thermal conductivity of the first spherical filler is less than 0.4 times the thermal conductivity of the blended material of the first amorphous filler and the first major agent, the thermal conductivity of the first spherical filler and the first bonding agent in the vicinity thereof becomes lower, and a singular hot spot occurs in the first bonding agent when a thermal flux is applied to the processing target substrate which is the ceramic plate and the adsorbed material.

When the thermal conductivity of the first spherical filler is larger than 1.0 times the thermal conductivity of the blended material of the first amorphous filler and the first major agent, the thermal conductivity of the first spherical filler and the first bonding agent in the vicinity thereof becomes higher, and a singular cold spot occurs in the first bonding agent when a thermal flux is applied to the processing target substrate which is the ceramic plate and the adsorbed material.

The 10th invention, according to the first invention, is characterized in that the Vickers hardness of the first spherical filler is smaller than the Vickers hardness of the ceramic plate.

Therefore, the thickness of the first bonding agent can be controlled to be greater than or equal to the average diameter of the first spherical filler. Making the Vickers hardness of the first spherical filler to be smaller than the Vickers hardness of the ceramic plate, even if an individual piece that is greater than the average diameter is dispersed and blended into the first spherical filler, the individual piece of the spherical filler that is greater than the average diameter is destroyed before the ceramic plate at the time of hot press curing the first bonding agent. Therefore, crack generation in the ceramic plate can be prevented without applying local stress to the ceramic plate.

The 11th invention, according to the first invention, is characterized in that relationships W1>D, W1>W2, and d1>d2 are satisfied in a cross-section of the heater in which a surface that is substantially parallel to the major surface of the ceramic plate is longer than a surface that is substantially perpendicular to the major surface of the ceramic plate, when W1 is a width of the each of the recesses, D is a depth of the each of the recesses, W2 is a width of the major surface between the recesses, d1 is a distance between a bottom face of the each of the recesses and a major surface of the heater, the major surface facing the bottom face, and d2 is a distance of a difference between a height of the major surface of the ceramic plate from the bottom face of the each of the recesses and a height of the major surface of the heater from the bottom face of the each of the recesses, the major surface of the heater facing the temperature regulating plate.

Satisfying the above relationship secures the uniformity of the in-plane temperature distribution of the ceramic plate. In addition, rapid heating and cooling of the ceramic plate becomes possible.

For example, a cross section of the heater is substantially a rectangular shape, and the long side of the cross section is substantially parallel to the major surface of the ceramic plate. By this, the heat from the heater can be uniformly and rapidly conducted to the ceramic plate. As a result, the processing target substrate placed on the ceramic plate can be uniformly and rapidly heated.

Further, it becomes possible to heat/cool the ceramic plate rapidly while securing the uniformity of the in-plane temperature distribution of the ceramic plate by satisfying relationships W1>D, W1>W2, and d1>d2 when W1 is the width of the each of the recesses, D is the depth of the each of the recesses, W2 is the width of the major surface between recesses, d1 is the distance between the bottom face of the each of the recesses and the major surface of the heater of the bottom face side, and d2 is the distance of the difference between the height of the major surface of the ceramic plate from the bottom face of the each of the recesses and the height of the major surface of the temperature regulating plate side of the heater from the bottom face of the each of the recesses.

If d1<d2, then the heater is closer to the ceramic plate side than when d1>d2. Therefore, the ceramic plate is susceptible to the effects of the rapid expansion and contraction of the heater. For example, a crack may be generated in the ceramic plate by the stress applied to the ceramic plate due to the expansion and contraction of the heater. Further, the in-plane temperature of the ceramic plate may also be susceptible to the effect of the pattern shape of the heater, in which case, uniformity may drop. Therefore, it is preferable that d1>d2.

The 12th invention, according to the 11th invention is characterized in that a tapered portion with a depth becoming gradually shallower toward an edge of the each of the recesses is provided on an edge region of the each of the recesses.

An adhesive is applied to the inner part of the each of the recesses prior to adhering the heater to the inner part of the each of the recesses. When the tapered portion with a depth becoming gradually shallower toward the edge of the each of the recesses is provided on the edge region of the each of the recesses, air bubbles are difficult to occur in the tapered portion at the time of applying the adhesive. Even if air bubbles were to occur, the air bubbles can be easily removed thereafter at the time of press bonding.

Further, when adhering the heater to the inner part of the each of the recesses, press bonding causes the large shaped first amorphous filler to flow out from within the each of the recesses. At this time, providing the tapered portion on the edge region of the each of the recesses allows easy outflow of the first amorphous filler having a large shape. As a result, the distance between the heater and the ceramic plate can be more uniformly controlled depending on the average grain size of the first spherical filler.

In addition, when the tapered portion is provided on the end part region of the each of the recesses, a pressure gradient is generated in the each of the recesses when the heater is pressed bonded, and as a result, there is increased precision of the positioning (centering) relative to the each of the recesses of the heater.

In the 13th invention, according to the first invention, the second bonding agent has a second major agent that includes an organic material, a second amorphous filler that includes an inorganic material, and a second spherical filler that includes an inorganic material. The second amorphous filler and the second spherical filler are dispersion-compounded into the second major agent, the second major agent, the second amorphous filler, and the second spherical filler are made of electrically insulating material, the average diameter of the second spherical filler is greater than the maximum value of all the minor axes of the second amorphous filler, a thickness of the second bonding agent is greater than or equal to the average diameter of the second spherical filler, and the average diameter of the second spherical filler is less than or equal to the average diameter of the first spherical filler.

The second bonding agent provided between the heater and the bottom face of the each of the recesses must be an adhesive material while being a heat conducting agent that efficiently conducts heat from the heater to the ceramic plate. Accordingly, similar to the first bonding agent, the amorphous filler is blended and dispersed in the second bonding agent. By this, the thermal conductivity of the second bonding agent becomes higher. The thickness of the second bonding agent is controlled by the average diameter of the second spherical filler. Further, the average diameter of the second spherical filler is less than or equal to the average diameter of the first spherical filler. By this, the second bonding agent can be formed with a uniform thickness that is thinner than the first bonding agent. By this, the uniformity of the in-plane temperature distribution of the ceramic plate is secured.

The 14th invention, according to the 13th invention, is characterized in that a thermal conductivity of the second spherical filler contained in the second bonding agent and a thermal conductivity of the second amorphous filler contained in the second bonding agent are higher than the thermal conductivity of the second major agent of the second bonding agent.

Because the thermal conductivity of the second spherical filler and the second amorphous filler is higher than the second major agent of the second bonding agent, the thermal conductivity of the second bonding agent rises more than the bonding agent of the major agent elemental substance and thus improves cooling performance.

The 15th invention, according to the 13th invention, is characterized in that the material of the second spherical filler and the material of the second amorphous filler are different.

The purpose of adding the second spherical filler to the second bonding agent is to provide uniformity in the thickness of the second bonding agent and for dispersing the stress applied to the ceramic plate. The purpose of adding the second amorphous filler to the second bonding agent is to improve the thermal conductivity of the second bonding agent and to provide uniformity in the thermal conductivity.

In this manner, selecting a more favored material that matches these purposes allows a better performance to be obtained.

The 16th invention, according to the 14th invention, is characterized in that the thermal conductivity of the second spherical filler is lower than the thermal conductivity of the second amorphous filler.

For example, when the second spherical filler contacts the bottom face of the each of the recesses provided on the ceramic plate, the difference between the thermal conductivity of this contact portion is lower than that of the other portions. By this, uniformity can be provided in the in-plane temperature distribution of the ceramic plate.

The 17th invention, according to the 16th invention, is characterized in that the thermal conductivity of the second spherical filler is less than or equal to the thermal conductivity of a blended material of the second amorphous filler and the second major agent.

By making the thermal conductivity of the second spherical filler to be less than or equal to the thermal conductivity of the blended material of the second amorphous filler and the second major agent, the thermal conductivity within the second bonding agent becomes further constant, and the generation of a singular point of temperature known as a hot spot or a cold spot within the second bonding agent can be suppressed at the time of thermal conduction.

The 18th invention, according to the 17th invention, is characterized in that the thermal conductivity of the second spherical filler is in a range not less than 0.4 times and not more than 1.0 times the thermal conductivity of a blended material of the second amorphous filler and the second major agent.

Making the thermal conductivity of the second spherical filler to be in a range not less than 0.4 times and not more than 1.0 times the thermal conductivity of a blended material of the second amorphous filler and the second major agent, enables the thermal conductivity within the second bonding agent to be more uniform. As a result, the generation of a singular point of temperature known as a hot spot or a cold spot within the second bonding agent can be suppressed at the time of thermal conduction.

The 19th invention, according the 13th invention, is characterized in that the width W1 of the each of the recesses and the width W2 of the major surface between the recesses satisfies a relationship of 20% W2/(W1+W2) 45%.

When W2/(W1+W2) is less than 20%, the area of the major surface of the ceramic plate is reduced by the increase in the area of the heater. By this, the number of spherical filler that contacts the major surface of the ceramic plate is reduced, and controlling the thickness of the first bonding agent according to the average diameter of the spherical filler becomes difficult. For example, when W2/(W1+W2) is less than 20%, the first bonding agent may become thinner in local areas. When W2/(W1+W2) is greater than 45%, the in-plane density of the heater is lowered and the uniformity of the in-plane temperature distribution of the ceramic plate drops. If the relationship of 20% W2/(W1+W2) 45% is satisfied, the thickness of the first bonding agent can be appropriately controlled by the average diameter of the spherical filler such that the in-plane temperature distribution of the ceramic plate is uniform.

The 20th invention, according to the 13th invention, is characterized in that an arithmetic mean roughness (Ra) of the bottom face of the recesses is greater than the arithmetic mean roughness (Ra) of the major surface of the ceramic plate, and a maximum height roughness (Rz) of the bottom face of the recesses is greater than the maximum height roughness (Rz) of the major surface of the ceramic plate.

By having the arithmetic mean roughness and the maximum height roughness of the bottom face within the recesses to be greater than the arithmetic mean roughness and the maximum height roughness of the major surface of the ceramic plate, promotes an anchor effect thereby improving the adhesion performance of the second bonding agent. When the adhesive force of the second bonding agent is weak, the heater may peel off from the ceramic plate. Further, because the heater rapidly expands and contracts according to the heating and cooling, the second bonding agent with a high adhesive force must be provided between the bottom face of the each of the recesses and the heater.

For example, the arithmetic mean roughness Ra of the bottom face of the recesses is regulated to be not less than 0.5 μm and not more than 1.5 μm, and the maximum height roughness Rz of the bottom face of the recesses is regulated to be not less than 4.0 μm and not more than 9.0 μm. Further, the arithmetic mean roughness Ra of the major surface of the ceramic plate is regulated to be not less than 0.2 μm and not more than 0.6 μm, and the maximum height roughness Rz of the major surface of the ceramic plate is regulated to be not less than 1.6 μm and not more than 5.0 μm.

The 21st invention, according to the 13th invention, is characterized in that a distance d2 of the difference between the height of the major surface of the ceramic plate from the bottom face of the each of the recesses and the height of the major surface of the heater from the bottom face of the each of the recesses, the major surface of the heater facing the temperature regulating plate, is such that d2≧10 μm.

If d2≧10 μm, the heater is not susceptible to the pressure from the spherical filler and crack generation in the ceramic plate can be suppressed. Further, when a variation in the flatness and thickness of the major surface of the heater is not more than 10 μm, and if d2≧10 μm, the variation in the flatness and thickness can be absorbed (mitigated) by the first bonding agent.

The 22nd invention, according to the 13th invention, is characterized in that an insulator film is formed on the major surface of the temperature regulating plate.

If the material of the temperature regulating plate is, for example, metal, then electric insulating reliability can be secured between the heater and the temperature regulating plate by forming an inorganic material film that is formed by an alumite treatment or spraying. Further, forming the insulating film to be porous improves the bonding strength of the first bonding agent due to the anchor effect.

In addition, the inorganic material film formed between the temperature regulating plate and the ceramic plate acts as a buffer to mitigate the thermal expansion difference between the temperature regulating plate and the ceramic plate. Further, after the inorganic material film is formed by spraying, grinding the inorganic material film top surface improves the flatness of the inorganic material film top surface more than the temperature regulating plate top surface. In other words, when the temperature regulating plate top surface is flatter, crack generation in the ceramic plate can be prevented without applying local stress to the ceramic plate that opposes the temperature regulating plate top surface during hot press curing of the first bonding agent.

### ADVANTAGEOUS EFFECTS OF INVENTION

According to the invention, an electrostatic chuck that can rapidly heat and cool a processing target substrate while suppressing crack generation in the ceramic plate is realized.

### BRIEF DESCRIPTION OF DRAWINGS

FIG. 1A is an essential part cross-sectional schematic view of an electrostatic chuck, FIG. 1B is a magnified view of the portion shown by arrow A in FIG. 1A, and FIG. 1C is a magnified view of the portion shown by the arrow B in FIG. 1B.

FIGS. 2A to 2C are schematic views when crack generation has occurred in the ceramic plate.

FIG. 3 is an essential part cross-sectional schematic view of the recess and the heater.

FIGS. 4A to 4C are cross-sectional SEM images of the bonding agent, and FIG. 4A is a cross-sectional SEM image of the bonding agent in which the spherical filler and the amorphous filler are blended and dispersed, FIG. 4B is a cross-sectional SEM image of the bonding agent in which the amorphous filler is blended and dispersed, and FIG. 4C is a cross-sectional SEM image of the recess.

FIG. 5 is a diagram for describing the minor axis of the amorphous filler.

FIG. 6 is an essential part cross-sectional schematic view according to a variation of an electrostatic chuck.

FIG. 7 is an essential part cross-sectional schematic view according to another variation of another electrostatic chuck.

FIG. 8 is a cross-sectional schematic view of the recess periphery of an electrostatic chuck.

FIGS. 9A and 9B are diagrams for describing one example of an effect of the electrostatic chuck.

### DESCRIPTION OF EMBODIMENTS

Detailed embodiments will be described hereinafter with reference to drawings. The embodiment described below also includes a description of means for resolving the problem given above.

First, descriptions will be given of terms used in the embodiment of the invention.

### (Ceramic Plate)

The ceramic plate is the stage of the electrostatic chuck on which the processing target substrate is placed. The ceramic plate is a ceramic sintered material designed with a uniform thickness. The flatness of the major surface of the ceramic plate is designed to be a predetermined range. If the respective thickness is uniform or the flatness of the respective major surface is secured, then it is unlikely that local stress will be applied to the ceramic plate at the time of hot press curing of the bonding agent. Further, the thickness of the bonding agent interposed between the ceramic plate and the temperature regulating plate can be controlled by the average diameter of the spherical filler.

The diameter of the ceramic plate is approximately 300 mm and the thickness is approximately 1 to 4 mm. The flatness of the ceramic plate is not more than 20 μm. The variation in the thickness of the ceramic plate is not more than 20 μm. It is more preferable that the variation in flatness and thickness of the ceramic plate is not more than 10 μm.

The ceramic plate is made of 99.9 wt % alumina, has an average crystal grain diameter of not more than 3 μm, and has a density of not less than 3.95 g/cm³. The configuration given above improves the strength of the ceramic plate making it difficult to crack at the time of bonding. In addition, the plasma durability of the ceramic plate is raised.

### (Bonding Agent)

The bonding agent is a bonding agent that adheres the ceramic plate to the temperature regulating plate, and adheres the ceramic plate to the heater. The bonding agent (also referred to as adhesive or bonding layer) is preferably a bonding agent of an organic material that has a low thermal curing temperature and maintains flexibility after curing for convenience. The material of the major agent of the bonding agent is any of silicon resin, epoxy resin, or fluororesin. For example, a silicon resin bonding agent or a fluororesin with a comparatively low hardness is used as the bonding agent. In the case of a silicon resin bonding agent, a two-liquid added type is more preferred. When using a two-liquid added type, there are good curing properties in the deep portions of the bonding agent and gas (void) generation hardly occurs at the time of curing compared to a deoximation type and dealcoholization type. Further, the curing temperature is lower with a two-liquid added type than with a one-liquid added type. By this, the stress generated in the bonding agent becomes smaller. Note that when high rigidity is desired in the bonding agent, an epoxy resin bonding agent, or a fluororesin resin, is used. Further, when high anti-plasma durability is desired in the bonding agent, a fluororesin bonding agent is used. In this manner, the characteristics of the major agents after the major agents are cured can be appropriately selected by changing the properties of the major agents of the major agent of the bonding agent.

### (Amorphous Filler)

The amorphous filler is an additive for increasing the thermal conductivity of the bonding agent. Therefore, it is preferred that the form thereof be amorphous. The thermal conductivity is higher with a bonding agent that blends and disperses the major agent of the bonding agent and the amorphous filler compared to a bonding agent with only the major agent. For example, in contrast to a thermal conductivity of approximately 0.2 (W/mK) with the major agent elemental substance of the bonding agent, the thermal conductivity increases to a range of 0.8 to 1.7 (W/mK) when the silicon major agent is blended with an alumina amorphous filler. Further, an amorphous filler with an average diameter of not less than two types may be blended and dispersed in order to improve the filling rate of the major agent of the bonding agent. The material of the amorphous filler is an inorganic material. Specifically, the material for example, alumina, aluminum nitride, silica, and the like is appropriate. The amorphous filler top surface may be treated in order to increase the affinity between the amorphous filler and the major agent of the bonding agent. The weight concentration of the amorphous filler is between 70 to 80 (wt %) relative to the major agent of the bonding agent.

### (Spherical Filler)

The spherical filler is an additive for controlling the thickness of the bonding agent. It is preferred that the form thereof be a sphere so as to control the thickness of the bonding agent. The material of the spherical filler is an inorganic material. However, the material of the spherical filler and the material of the amorphous material are different. The material, for example, glass or the like is appropriate for spherical filler. When the filler shape is spherical, blending and dispersing into the bonding agent becomes easier. In addition, at the time of bonding, even if an amorphous filler exists between the spherical filler and the ceramic plate, because the shape of the spherical filler is spherical, the amorphous filler moves easily within the bonding agent. It is preferred that the shape of the spherical filler be close to a spherical form and that there is a narrow distribution of diameter. By this, the thickness of the bonding agent can be controlled more accurately. Further, having the diameter of the spherical filler to be greater than the amorphous filler is more preferred in controlling the bonding agent.

The term “spherical” of the spherical filler refers to not only a spherical form but also shapes that approximate a spherical form, in other words, not less than 90% of the overall grains are within a form factor range of 1.0 to 1.4. Here, the form factor is calculated from the average value of the ratio of the major axis of several hundred (for example, 200) grains, magnified and observed by a microscope, to the minor axis that is orthogonal to the long diameter. Accordingly, the form factor is 1.0 only if it is a perfectly spherical grain, and the form factor becomes non-spherical as it moves away from 1.0. Further, the term amorphous referred to here refers to that which exceeds a form factor of 1.4.

Note that the grain diameter distribution width of the spherical filler is narrower than the grain diameter distribution width of the amorphous filler. In other words, the variation of the grain diameter of the spherical filler is smaller than the variation of the grain diameter of the amorphous filler. Here, the grain diameter distribution width is defined by using, for example, the half value width of the grain diameter distribution, half of the half value width of the grain diameter distribution, a standard deviation, and the like.

The purpose of adding the spherical filler to the bonding agent is to provide uniformity in the thickness of the bonding agent and for dispersing the stress applied to the ceramic plate. Meanwhile, the purpose of adding the amorphous filler to the bonding agent is to increase the thermal conductivity of the bonding agent and to provide uniformity in the thermal conductivity. In this manner, selecting a more favored material that matches these purposes allows a better performance to be obtained.

For example, the diameter distribution of the first spherical filler is similar to the following distribution according to the JIS R6002 (test method for grains in abrasives for use with grind stones) screening test method.

The first spherical filler has a diameter distribution in which 10% diameter and 90% diameter fall within +/−10% of 50% diameter. Here, 90% diameter is a diameter of the spherical filler in which 90% remains on the mesh with a 90 μm mesh, and a 50% diameter is a diameter of the spherical filler in which 50% remains on the mesh with a 100 μm mesh, and a 10% diameter is a diameter of the spherical filler in which 10% remains on the mesh with a 110 μm mesh. In this embodiment, a target value of 50% diameter will be used for the first spherical filler.

### (Average Diameter)

The average diameter is a value that is the numerical value of the sum of all the spherical filler diameters divided by the number of all the spherical fillers.

### (Minor Axis)

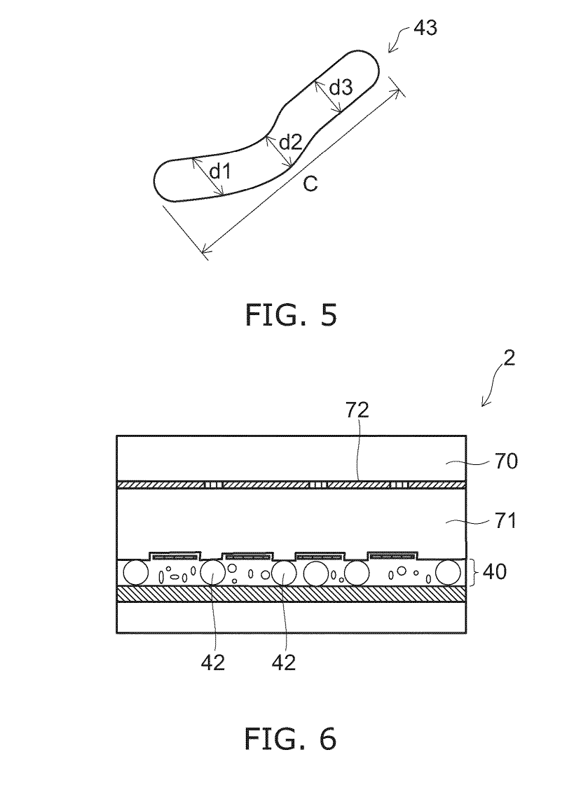

The minor axis is the length of the short direction that is orthogonal to the longitudinal direction of the amorphous filler (see FIG. 5).

### (Maximum Value of the Minor Axis)

The maximum value of the minor axis is the largest minor axis value from among all the minor axes of the amorphous filler.

### (Vickers Hardness)

The Vickers hardness of the first spherical filler is preferably smaller than the Vickers hardness of the ceramic dielectric.

Therefore, the thickness of the first bonding agent can be controlled to be greater than or equal to the average diameter of the first spherical filler. Making the Vickers hardness of the first spherical filler to be smaller than the Vickers hardness of the ceramic dielectric, even if an individual piece that is greater than the average diameter is dispersed and blended into the first spherical filler, the individual piece of the spherical filler that is greater than the average diameter is destroyed before the ceramic dielectric at the time of hot press curing the first bonding agent. Therefore, crack generation in the ceramic dielectric can be prevented without applying local stress to the ceramic dielectric.

Here, the test method of the Vickers hardness was implemented according to JIS R 1610. The Vickers hardness test equipment used an instrument rated to either JIS B 7725 or JIS B 7735.

### (Width)

The width refers to the width of a cross section where a member is cut in a direction that is orthogonal to the direction that each member extends (longitudinal direction).

### (Electrode)

Electrodes are internally provided parallel to the major surface in the inner part of the ceramic plate. The electrodes are formed integrally sintered with the ceramic plate. Or, a structure may also be used that interposes the electrodes between two ceramic plates.

### (Recess (Groove Portion))

The recess (groove portion) is a groove with a recessed shape provided on the back face side of the ceramic plate. The heater is adhered within this recess (groove portion). The recess is formed on the major surface of the ceramic plate by, for example, sand blasting or etching. If, for example, the thickness of the heater is 50 μm and the thickness of the first bonding agent is 50 μm, then the depth of the recess is not less than 100 μm and preferably not less than 110 μm. Further, the R processing size of the corner within the recess is preferably not more than a 330 μm radius. When the width of the heater is 2 mm, the width of the recess is preferably between 2.3 mm to 2.9 mm.

### (Heater)

The heater is a heater for heating the ceramic plate. The heater is a thin plate shaped metal. A cross-sectional shape of the heater is a rectangle or a trapezoid. With either shape, the thickness of the bonding agent interposed between the heater and the ceramic plate is easily made to be constant. Therefore, adhesion of the heater is favorable. Particularly, when the cross-sectional shape of the heater is a trapezoid, interference between the R processed portion within the recess and the end of the heater does not easily occur due to the arranging the short edge side thereof on the bottom face side of the recess. In regard to the trapezoid shape, a favorable adhesive force can be maintained without flexion of the heater as long as the difference between the long side and the short side of the trapezoid is between 0.6 to 1.0 times the thickness of the heater.

The thickness of the heater is preferably not more than 100 μm, and more preferably 50 μm. Further, the tolerance (the difference between the maximum thickness and the minimum thickness) of the thickness of the heater is preferably no greater than +/−1.5% of the thickness and more preferably not more than +/−1.0% of the thickness. By this, the heat generated from the heater can be uniform.

### (Temperature Regulating Plate (Temperature Regulating Part))

The temperature regulating plate is a plate for cooling or heating the ceramic plate. Therefore, a medium path where a cooling medium or thermal medium flows is provided within the temperature regulating plate. The cooling medium or thermal medium is connected via piping to a chilling machine.

The material of the temperature control plate preferably has properties of not causing contamination, not generating dust or the like during the processing of the processing target substrate. Materials for example, metals such as stainless steel, aluminum, titanium, and the like, an alloy of these, or a composite material in which a metal and ceramic is dispersed and blended is appropriate for the temperature regulating plate.

Further, an insulating film may be formed on the top surface of the temperature regulating plate to ensure electrical insulation between the heater and the temperature regulating plate. For example, an alumina sprayed film is appropriate for the insulating film. The alumina spray enables manufacturing with an easy process and at a low cost. When the temperature regulating plate material is aluminum, an alumite (registered trademark) treatment may be performed on the top surface of the temperature regulating plate. Sealing with alumite enables the reliability of the electrical insulation to be further improved.

Further, forming the insulating film to be porous improves the bonding strength of the bonding agent due to the anchor effect. In addition, the inorganic material film formed between the temperature regulating plate and the ceramic plate acts as a buffer to mitigate the thermal expansion difference between the temperature regulating plate and the ceramic plate. Further, after the inorganic material film is formed by spraying, grinding the inorganic material film top surface may improve the flatness of the inorganic material film top surface more than the temperature regulating plate top surface. In other words, when the temperature regulating plate top surface is flatter, crack generation in the ceramic plate can be prevented without applying local stress to the ceramic plate that opposes the temperature regulating plate top surface during hot press curing of the first bonding agent.

Further, adhering a ceramic plate having a built-in heater to the temperature regulating plate and rapidly heating the ceramic plate by the heater may also cause the temperature of the ceramic plate to suddenly rise more than the temperature regulating plate. On account of this, the ceramic plate suddenly undergoes thermal expansion. However, even if the ceramic plate undergoes thermal expansion on the temperature regulating plate, because the shape of the spherical filler contained in the bonding agent is spherical, the spherical filler exhibits what is known as a “rolling motion”. Accordingly, when the spherical filler is contained in the bonding agent, the thickness of the bonding agent is difficult to change even if the ceramic plate undergoes thermal expansion on the temperature regulating plate. In contrast to this, if only the amorphous filler is contained in the bonding agent without the spherical filler, then the thickness of the bonding agent will change in accordance with the thermal expansion of the ceramic plate. On account of this, there may also be negative effects on the reliability of the temperature control such as the in-plane temperature distribution of the ceramic plate may be uneven. Therefore, it is preferred that the spherical filler is contained within the bonding agent.

The Vickers hardness of the ceramic plate 10 is not less than 15 GPa.

Next, a description will be provided of the configuration of the electrostatic chuck according to this embodiment. Content that duplicates the description of terms given above will be appropriately omitted.

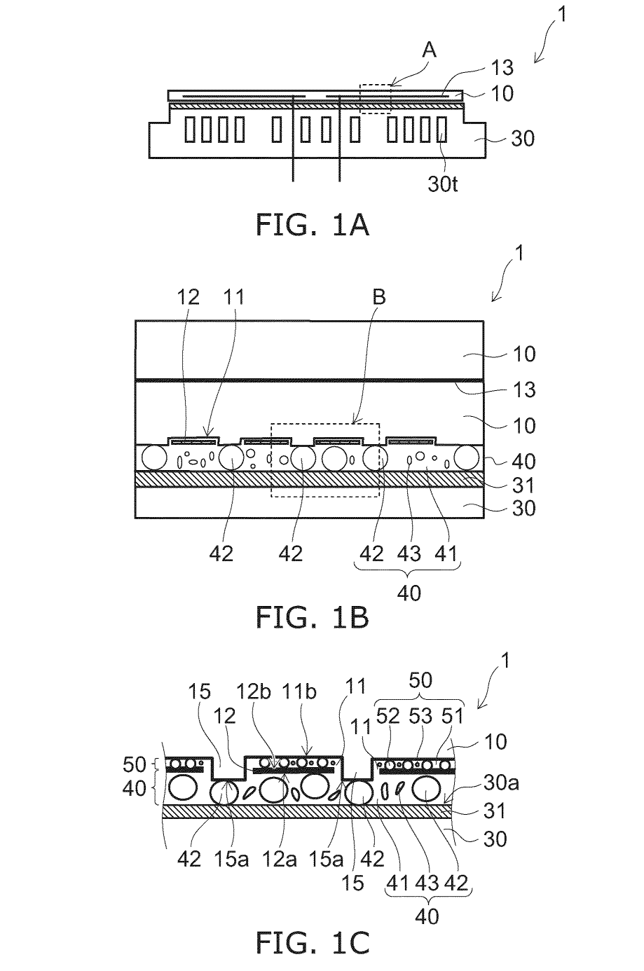

FIG. 1A is a cross-sectional schematic view of a relevant part of an electrostatic chuck; FIG. 1B is a magnified view of the portion shown by arrow A in FIG. 1A; and FIG. 1C is a magnified view of the portion shown by the arrow B in FIG. 1B.

First, a description will be given of an overview of the electrostatic chuck 1.

The electrostatic chuck 1 is provided with a ceramic plate 10, a temperature regulating plate 30 bonded to the ceramic plate 10, a first bonding agent 40 provided between the ceramic plate 10 and the temperature regulating plate 30, and a heater 12 provided in a recess 11 of the ceramic plate 10. The recess 11 of the ceramic plate 10 is provided on a major surface (lower surface side) of the ceramic plate 10. An electrode 13 is provided in the inner part of the ceramic plate 10.

The bonding agent 40 has a first major agent 41 that includes an organic material, a first amorphous filler 43 that includes an inorganic material, and a first spherical filler 42 that includes an inorganic material. The amorphous filler 43 and the spherical filler 42 are dispersion-compounded into the major agent 41, and the major agent 41, the amorphous filler 43, and the spherical filler 42 are electrically insulating materials. The average diameter of the spherical filler 42 is greater than the maximum value (for example, 60 μm) of all the minor axes of the amorphous filler 43. The thickness of the bonding agent 40 is greater than or equal to the average diameter of the spherical filler 42. The width of the recess 11 is wider than the width of the heater 12, and the depth of the recess 11 is greater than the thickness of the heater 12.

The thermal conductivity of the spherical filler 42 is less than or equal to the thermal conductivity of a blended material of amorphous filler 43 and the major agent 41.

By making the thermal conductivity of the spherical filler 42 to be less than or equal to the thermal conductivity of the blended material of the amorphous filler 43 and the major agent 41, the thermal conductivity within the bonding agent 40 becomes further constant, and the generation of a singular point of temperature known as a hot spot or a cold spot within the bonding agent 40 can be suppressed at the time of thermal conduction.

The thermal conductivity of the spherical filler 42 is in a range not less than 0.4 times and not more than 1.0 times the thermal conductivity of a blended material of the amorphous filler 43 and the major agent 41.

Making the thermal conductivity of the spherical filler 42 to be in a range not less than 0.4 times and not more than 1.0 times the thermal conductivity of the blended material of the amorphous filler 43 and the major agent 41, enables the thermal conductivity within the bonding agent 40 to be more uniform. As a result, the generation of a singular point of temperature known as a hot spot or a cold spot within the bonding agent 40 can be suppressed at the time of thermal conduction.

When the thermal conductivity of the spherical filler 42 is less than 0.4 times the thermal conductivity of the blended material of the amorphous filler 43 and the major agent 41, the thermal conductivity of the spherical filler 42 and the bonding agent 40 in the vicinity thereof becomes lower, and a hot spot occurs when a thermal flux is applied to the ceramic plate 10 and the processing target substrate which is an adsorbed material.

When the thermal conductivity of the spherical filler 42 is more than 1.0 times the thermal conductivity of the blended material of the amorphous filler 43 and the major agent 41, the thermal conductivity of the spherical filler 42 and the bonding agent 40 in the vicinity thereof becomes higher, and a hot spot occurs when a thermal flux is applied to the ceramic plate 10 and the processing target substrate which is an adsorbed material.

The Vickers hardness of the spherical filler 42 is preferably less than the Vickers hardness of the ceramic plate 10. The thickness of the bonding agent 40 can be controlled to be greater than or equal to the average diameter of the spherical filler 42 or greater than the average diameter depending on the spherical filler 42. Making the Vickers hardness of the spherical filler 42 to be smaller than the Vickers hardness of the ceramic plate 10, even if an individual piece that is greater than the average diameter is dispersed and blended into the spherical filler 42, the individual piece of the spherical filler 42 that is greater than the average diameter is destroyed before the ceramic plate 10 at the time of hot press curing the bonding agent 40. Therefore, crack generation in the ceramic plate 10 can be prevented without applying local stress to the ceramic plate 10.

Specifically, in the material of the bonding agent 40, the major agent 41 is silicon resin, the amorphous filler 43 is alumina particles, and the spherical filler is soda lime glass. The thermal conductivity of the blended material of the major agent 41 and the amorphous filler 43 is 1.0 W/mK, and the thermal conductivity of the spherical filler 42 is 0.7 W/mK. Further, the Vickers hardness of the spherical filler 42 is not more than 6 Gpa.

Here, the measurement method of the thermal conductivity is implemented according to JIS R 1611 for the spherical filler 42. Further, measurement of the thermal conductivity for the blended material of the major agent 41 and the amorphous filler 43 was performed using a QTM-D3 thermal conductivity meter made by Kyoto Electronics.

The heater 12 is bonded inside the recess 11 by a second bonding agent 50. The bonding agent 50 is provided between the bottom face 11b of the recess 11 and the heater 12. The details of the bonding agent 50 will be described below.

A first distance between a major surface 12a of the temperature regulating plate 30 side of the heater 12 and a major surface 30a of the temperature regulating plate 30 is longer than a second distance between a top surface 15a of a protrusion 15 between recesses 11 of the ceramic plate 10 and a major surface 30a of the temperature regulating plate 30. The top surface 15a of the protrusion 15 is the major surface of the temperature regulating plate 30 side of the ceramic plate 10. A description will be given hereinafter of the major surface of the ceramic substrate 10 using the terminology of the top surface 15a of the protrusion 15 in the embodiment.

A detailed description will be given of the configuration of the electrostatic chuck 1.

The ceramic plate 10 is a Coulombic type raw material with a volume resistivity (20° C.) of not less than 10¹⁴ Ω·cm. Because the ceramic plate 10 is a Coulombic type raw material, the adsorptive power of the processing target substrate and the desorption responsiveness of the processing target substrate are stable even when the temperature during treatment of the processing target substrate changes. Further, the diameter thereof is 300 mm, and the thickness is between 1 to 4 mm. The electrode 13 is provided in the inner part of the ceramic plate 10 so as to follow the major surface of the ceramic plate 10. The ceramic plate 10 is formed by integrally sintering with the electrode 13. When a voltage is applied to the electrode 13, the ceramic plate 10 takes on static electricity. By this, the processing target substrate undertakes electrostatic adsorption on the ceramic plate 10. The total area of the electrode 13 is between 70% to 80% of the area of the major surface of the ceramic plate 10. The thickness of the electrode 13 is, for example, 0.8 μm.

The heater 12 is a plate shaped metal. The material of the heater 12 is, for example, stainless steel (SUS). The thickness thereof is 50 μm. The width of the heater 12 is 2 mm. The heater 12 is bonded by the second bonding agent 50 (thickness of 50 μm) to the bottom face 11b of the recess 11 of the ceramic plate 10.

The depth of the recess 11 is, for example, 130 μm. The width of the recess 11 is, for example, 2.4 mm. Accordingly, the major surface 12a of the temperature regulating plate side of the heater 12 is drawn in about 30 μm to the ceramic plate 10 side more than the top surface 15a of the protrusion 15. Note that the R process is implemented at the corner of the recess 11. The R processing size of the corner in the recess 11 is a 0.27 mm radius.

The major component of the temperature regulating plate 30 is aluminum (Al:A6061) or an alloy of aluminum and silicon carbide (SiC). In addition, a medium path 30t is formed in the inner part on the temperature regulating plate 30 by low embossing. A medium for regulating temperature is circulated in the medium path 30t. The diameter of the temperature regulating plate 30 is 320 mm, and the thickness is 40 mm. An insulating film 31 is formed as necessary on the major surface 30a of the temperature regulating plate 30. The insulating film 31 is the spray film, alumite film, and the like described above.

The bonding agent 40 has the major agent 41, the spherical filler 42, and the amorphous filler 43. The bonding agent 40 is formed by vacuum bonding, hot press curing, and the like, between the ceramic plate 10 and the temperature regulating plate 30. For example, the spherical filler 42 and the amorphous filler 43 are blended and dispersed in the major agent 41. The concentration of the amorphous filler 43 is approximately 80 wt % of the bonding agent 40. The average diameter of the spherical filler 42 is approximately 100 μm, and more specifically, the 90% diameter is 97.5 μm, the 50% diameter is 100.2 μm, and the 10% diameter is 104.3 μm. By making the average diameter of the spherical filler 42 to be 100 μm, the average diameter of the spherical filler 42 are greater than the maximum value (60 μm) of all the minor axes of the amorphous filler 43. In the electrostatic chuck 1, electrical insulating properties can be secured around the heater 12 by having the temperature regulating plate 30 oppose the ceramic plate 10 with the heater 12 is formed and integrate these by adhering with the bonding agent 40.

Note that the average diameter of the spherical filler 42 is not limited to 100 μm. The average diameter of the spherical filler 42 may be a range from 70 to 100 μm.

Further, because the spherical filler 42 and the amorphous filler 43 are inorganic materials, the respective sizes thereof (for example, the diameter) are easily controlled. Therefore, blending and dispersing of the bonding agent 40 with the major agent 41 is easily done. Because the major agent 41 of the bonding agent 40, the amorphous filler 43, and the spherical filler 42 are electrically insulating materials, electrical insulating properties can be secured around the heater 12.

Further, the average diameter of the spherical filler 42 is greater than the maximum value of all the minor axes of the amorphous filler 43. Therefore, with the first spherical filler 42, the thickness of the bonding agent 40 can be controlled to be greater than or equal to the average diameter of the first spherical filler 42. By this, crack generation in the ceramic plate 10 can be prevented at the time of hot press curing of the bonding agent 40 without applying local stress to the ceramic plate 10 by the amorphous filler 43. Further, a first distance between a major surface 12a of the temperature regulating plate 30 side of the heater 12 and a major surface 30a of the temperature regulating plate 30 is longer than a second distance between a top surface 15a of a protrusion 15 between recesses 11 of the ceramic plate 10 and a major surface 30a of the temperature regulating plate 30. Therefore, stress becomes more difficult to conduct at the time of hot press curing to the heater 12 by the spherical filler 42. Therefore, crack generation in the ceramic plate 10 can be prevented without the pressure at the time of hot press curing being conducted to the thin ceramic plate 10 in the recess 11 via the heater 12. Further, because the bonding agent 40 and the bonding agent 50 reside above and below the heater 12, the stress due to the heater 12 is difficult to transfer to the ceramic plate 10 even if the heater 12 rapidly expands and contracts. The result is that crack generation in the ceramic plate 10 is suppressed.

Further, if the thickness of the bonding agent 40 is approximately 100 μm thick, the linear expansion difference between the ceramic plate 10 and the temperature regulating plate 30 is absorbed by the bonding agent 40. Therefore, deformation of the ceramic plate 10 and peeling of the bonding agent 40 are difficult to occur.

The average diameter of the spherical filler 42 that is blended and dispersed into the first bonding agent 40 is verified as follows

First, Table 1 shows the thickness of the bonding agent 40 when only the amorphous filler 43 is blended and dispersed into the major agent 41 without the spherical filler 42 being blended and dispersed. A total of 26 samples, No. 1 to 26, were prepared as measurement samples. The variation in the thickness of the bonding agent 40 was determined from these samples. Each sample mutually adhered ceramic plates having a diameter of 300 mm by hot press curing with bonding agent 40 in which only the amorphous filler 43 was blended and dispersed into the major agent 41.

There is a total of 17 measurement points for each sample with 8 locations on the peripheral part, 8 locations in the intermediate part, and one location in the center part. The thickness of the thickest part, the thickness of the thinnest part, and the average thickness were determined for each sample from these locations.

As shown in Table 1, the thickest part of the bonding agent 40 has a variation in a range between 22 to 60 μm. The thinnest part of the bonding agent 40 has a variation in a range between 3 to 46 μm. In other words, when the longitudinal direction of the amorphous filler 43 is not parallel to the major surface of the ceramic plate 10, the minor axis of the amorphous filler 43 can be presumed to have a variation within the range between 3 to 60 μm. In this case, the maximum value of the minor axis of the amorphous filler 43 can be presumed to be 60 μm.

Note that when the longitudinal direction of the amorphous filler 43 is substantially perpendicular to the major surface of the ceramic plate 10, the major axis of the amorphous filler 43 can be presumed to have a variation within the range between 3 to 60 μm. In this case, the maximum value of the long diameter of the amorphous filler 43 can be presumed to be 60 μm.

TABLE 1
Variation of bonding agent thickness

| | | Adhesion | Adhesion | Adhesion | | | Bonding | Bonding | Bonding |
|---|---|---|---|---|---|---|---|---|---|
| | Spherical | layer | layer | layer | | Spherical | agent | agent | agent |
| Test | filler | thickest | thinnest | average | Test | filler | thickest | thinnest | average |
| No. | addition | part (μm) | part (μm) | (μm) | No. | addition | part (μm) | part (μm) | (μm) |
| 1 | no | 37 | 28 | 33 | 14 | no | 45 | 26 | 36 |
| 2 | no | 33 | 15 | 26 | 15 | no | 53 | 24 | 39 |
| 3 | no | 22 | 10 | 17 | 16 | no | 45 | 23 | 35 |
| 4 | no | 27 | 17 | 23 | 17 | no | 42 | 24 | 33 |
| 5 | no | 23 | 14 | 19 | 18 | no | 57 | 43 | 51 |
| 6 | no | 39 | 12 | 26 | 19 | no | 23 | 9 | 18 |
| 7 | no | 27 | 3 | 18 | 20 | no | 51 | 13 | 32 |
| 8 | no | 35 | 12 | 23 | 21 | no | 60 | 8 | 34 |
| 9 | no | 33 | 5 | 17 | 22 | no | 46 | 18 | 29 |
| 10 | no | 57 | 17 | 30 | 23 | no | 48 | 10 | 25 |
| 11 | no | 47 | 14 | 29 | 24 | no | 37 | 3 | 15 |
| 12 | no | 48 | 22 | 34 | 25 | no | 58 | 27 | 45 |
| 13 | no | 60 | 46 | 52 | 26 | no | 28 | 3 | 18 |

Maximum value of bonding agent thickest part 60 μm, Minimum value 32 μm
Maximum value of bonding agent thinnest part 46 μm,

In actuality, the generation of cracks were seen in the ceramic plate 10 when manufacturing the electrostatic chuck according to the manufacturing processes 1 to 5 as given below when using the bonding agent 40 in which only the amorphous filler 43 is blended and dispersed into the major agent 41.

The manufacturing process includes the processes 1 to 5 as follows.

(1) First, each ceramic plate 10 and temperature regulating plate 30 is prepared individually.
(2) Next, the amorphous filler 43 is blended and dispersed into the major agent 41 of the bonding agent 40 and the spherical filler 42 is further blended and dispersed. Blending and dispersion is done by a mixing machine.
(3) Next, the bonding agent 40 is applied to the respective bonding surfaces of the ceramic plates 10 and the temperature regulating plates 30 and placed into a vacuum chamber. Vacuum bonding is performed by applying a vacuum to a vacuum chamber and mutually aligning the applied bonding agent 40.
(4) Next, after vacuum bonding, hot press curing is done by a hot press curing machine. In this process, the thickness of the bonding agent 40 is appropriately regulated. After hot press curing, curing of the bonding agent 40 is performed in an oven.
(5) After curing, a grinding process is performed on the ceramic plate 10 until a prescribed thickness to form the adsorption face of the electrostatic chuck. For example, grinding is performed on the ceramic plate 10 until a predetermined thickness (1 mm), and a polishing process is performed.

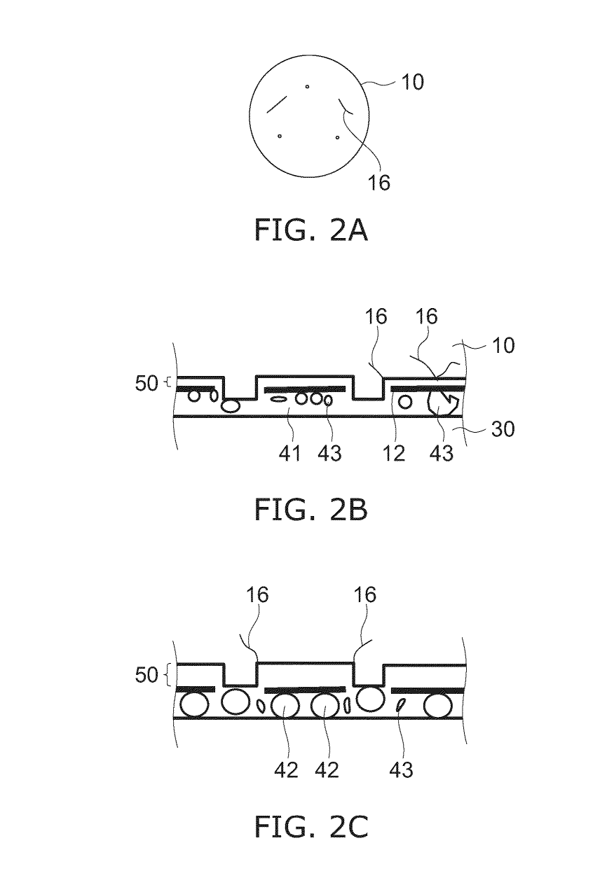

No generation of cracks in the ceramic plate 10 were observed immediately after completing curing of the bonding agent 40. However, crack generation was observed during the grinding process of the top surface of the ceramic plate 10. For example, such condition is shown in FIGS. 2A and 2B.

FIGS. 2A to 2C are schematic views of when crack generation has occurred in the ceramic plate.

FIG. 2A is a schematic view of the top surface of the ceramic plate 10 after the surface grinding process. As illustrated in the drawing, the crack 16 occurs from the inner part of the ceramic plate 10 and the end ends at the inner part of the ceramic plate 10.

A description will be given of the cause thereof using FIG. 2B.

As shown in FIG. 2B, when hot press curing is performed while a large amorphous filler 43 of approximately 60 μm is interposed between the ceramic plate 10 and the temperature regulating plate 30, stress is concentrated in the area where the amorphous filler 43 abuts the heater 12. It is presumed that, starting in this area, the stress is transferred to the ceramic plate 10 via the heater 12, and the crack 16 is generated. Particularly, because the thickness of the ceramic plate 10 is thin at the bottom face 11b of the recess, it is preferred that stress is not applied to this area.

However, if the average diameter of the spherical filler 42 is greater (for example, 100 μm) than the maximum value (60 μm) of the minor axis of the amorphous filler 43, crack generation as described above can be suppressed because the spherical filler 42 contacts the top surface 15a of the protrusion 15 of the ceramic plate 10 at the time of hot press curing.

However, as shown in FIG. 2C, when the major surface 12a of the temperature regulating plate 30 side of the heater 12 is protruding to the temperature regulating plate 30 side more than the top surface 15a of the protrusion 15, the spherical filler 42 abuts the heater 12. In this case, the stress is transferred to the ceramic plate 10 via the heater 12, and the crack 16 is also generated.

In this embodiment, as shown in FIG. 1C, because the major surface 12a of the temperature regulating plate 30 side of the heater 12 is drawn in approximately 30 μm to the ceramic plate 10 side more than the top surface 15a of the recess 15, the spherical filler 42 does not apply pressure to the heater 12.

Table 2 shows the thickness result of the bonding agent 40 for when the spherical filler 42 and the amorphous filler 43 are blended and dispersed into the major agent 41. The average diameter of the spherical filler 42 used here is 70 μm.

A total of 4 samples, No. 31 to 34, were prepared as measurement samples. The variation in the thickness of the bonding agent 40 was found from these samples. Each sample mutually adhered ceramic plates having a diameter of 300 mm by hot press curing with bonding agent 40 in which the spherical filler 42 and the amorphous filler 43 were blended and dispersed into the major agent 41.

There is a total of 17 measurement points for each sample with 8 locations on the peripheral part, 8 locations in the intermediate part, and one location in the center part. The thickness of the thickest part, the thickness of the thinnest part, and the average thickness of 17 locations were found for each sample from these locations.

As shown in Table 2, the thickest part of the bonding agent 40 is held within a range between 65 to 68 μm. The thinnest part of the bonding agent 40 is held within a range between 57 to 61 μm. In other words, the results of Table 2 indicate that the degree of variation has dropped more so than the results of Table 1. In other words, it is discovered that the variation in the average thickness, the thickest part, and the thinnest part of the bonding agent 40 is smaller when blending and dispersing the spherical filler 42 than compared to when the spherical filler 42 is not blended and dispersed. Further, it is discovered that the average thickness of the bonding agent 40 approximates the average diameter (70μm) of the spherical filler. Note that similar results were obtained even when a 100 μm sample was used as the average diameter for the spherical filler 42.

TABLE 2
Variation of bonding agent thickness

| | | Bonding | Bonding | Bonding |
|---|---|---|---|---|
| | Spherical | agent | agent | agent |
| | filler | thickest part | thinnest part | average |
| Test No. | addition | (μm) | (μm) | (μm) |
| 31 | 70 μm | 67 | 61 | 64 |
| 32 | 70 μm | 65 | 61 | 62 |
| 33 | 70 μm | 65 | 57 | 63 |
| 34 | 70 μm | 68 | 60 | 64 |

Maximum value of bonding agent thickest part 68 μm, Minimum value 61 μm
Maximum value of bonding agent thinnest part 61 μm, Minimum value 57 μm

In actuality, the generation of cracks were not seen in the ceramic plate 10 when the electrostatic chuck was manufactured according to the manufacturing processes 1 to 5 as given above when using the bonding agent 40 in which the spherical filler 42 and the amorphous filler 43 are blended and dispersed into the major agent 41.

In this manner, when the average diameter of the spherical filler 42 is greater than the maximum value of all the minor axes of the amorphous filler 43, the thickness of the bonding agent 40 can be more than or equal to the average diameter of the spherical filler 42 depending on the spherical filler 42. As a result, crack generation in the ceramic plate 10 can be prevented at the time of hot press curing of the bonding agent 40 and the application of local stress to the ceramic plate 10 by the amorphous filler 43 becomes more difficult.

Further, in this embodiment, the average diameter of the spherical filler 42 is configured to be 10 μm more than or equal to the maximum value of minor axis of the amorphous filler 43.

When the average diameter of the spherical filler 42 is 10 μm more than or equal to the maximum value of the minor axis of the amorphous filler 43, the thickness of the bonding agent 40 can be controlled by the average diameter of the spherical filler 42 and not by the size of the amorphous filler 43 at the time of hot press curing the bonding agent 40. This is because the spherical filler 42 contacts the top surface 15a of the protrusion 15 of the ceramic plate 10 at the time of hot press curing. In addition, the major surface 12a of the temperature regulating plate side of the heater 12 is drawn in to the ceramic plate 10 side more than the top surface 15a of the protrusion 15.

In other words, the application of local stress via the heater 12 to the ceramic plate 10 is difficult at the time of hot press curing on account of the amorphous filler 43 and the spherical filler 42. By this, crack generation in the ceramic plate 10 can be prevented.

Further, when the variation in the flatness and thickness of the temperature regulating plate 30 and the ceramic plate 10 positioned above and below the bonding agent 40 is not more than 10 μm (for example, 5 μm), the surface roughness of the temperature regulating plate 30 and the ceramic plate 10 can be mitigated (absorbed) by the bonding agent 40 by making the average diameter of the spherical filler 42 to be 10 μm more than equal to the maximum value of the minor axis of the amorphous filler 43.

Further, the rigidity of the ceramic plate 10 is increased by the temperature regulating plate 30 residing on the lower side of the ceramic plate 10. Further, cracked generation in the ceramic plate 10 can be prevented at the time of processing the ceramic plate 10. Dispersion-compounding the spherical filler 42 into the bonding agent 40 enables the ceramic plate 10 to be clamped at a uniform thickness. As a result, damage is not inflicted on the ceramic plate 10 even when a process is implemented on the ceramic plate 10.

Further, when the temperature regulating plate 30 is made of metal, the linear expansion coefficient of the temperature regulating plate 30 is greater than the linear expansion coefficient of the ceramic plate 10. Interposing the bonding agent 40 between the temperature regulating plate 30 and the ceramic plate 10 makes the thermal expansion and contraction difference between the ceramic plate 10 and the temperature regulating plate 30 easy to be absorbed within the bonding agent 40. As a result, deformation of the ceramic plate 10 and peeling of the ceramic plate 10 and the temperature regulating plate 30 difficult to occur.

Further, the bonding agent 50 that is interposed between the heater 12 and the bottom face 11b of the recess 11 has a second major agent 51 that includes an organic material, a second amorphous filler 53 that includes an inorganic material, and a second spherical filler 52 that includes an inorganic material. The amorphous filler 53 and the spherical filler 52 are dispersion-compounded into the major agent 51. The major agent 51, the amorphous filler 53, and the spherical filler 52 are electrically insulating materials. The average diameter of the spherical filler 52 is greater than the maximum value of all the minor axes of the amorphous filler 53. The thickness of the bonding agent 50 is more than or equal to the average diameter of the spherical filler 52. The average diameter of the spherical filler 52 is less than or equal to the average diameter of the first spherical filler 42. The bonding agent 50 is formed by vacuum bonding, hot press curing, and the like, between the ceramic plate 10 and the heater 12. For example, the spherical filler 52 and the amorphous filler 53 are blended and dispersed in the major agent 51. The concentration of the amorphous filler 53 is approximately 80 wt % of the bonding agent 50. The average diameter of the spherical filler 52 is approximately 50 μm, and more specifically, the 90% diameter is 48.0 μm, the 50% diameter is 50.4 μm, and the 10% diameter is 52.8 μm.

The bonding agent 50 also functions as a heat conducting agent that efficiently conducts heat from the heater 12 to the ceramic plate 10. Accordingly, similar to the bonding agent 40, the amorphous filler 53 is blended and dispersed in the bonding agent 50. By this, the thermal conductivity of the bonding agent 50 increases. The thickness of the bonding agent 50 is controlled by the average diameter of the spherical filler 52.

Further, because the spherical filler 52 and the amorphous filler 53 are inorganic materials, the respective sizes thereof (for example, the diameter) are easily controlled. Therefore, blending and dispersing of the bonding agent 50 with the major agent 51 is easily done. Because the major agent 51 of the bonding agent 50, the amorphous filler 53, and the spherical filler 52 are electrically insulating materials, electrical insulating properties can be secured around the heater 12.

Note that although the average diameter of the spherical filler 52 is 50 μm and is less than the maximum value of the minor axis of the amorphous filler 53, an area that becomes partially thicker does not exist in the bonding agent 50 because an operation is performed to scoop out the excess bonding agent 50 within the recess 11 while restraining the heater 12 when bonding the heater 12 within the recess 11.

Further, the average diameter of the spherical filler 52 is less than or equal to the average diameter of the spherical filler 42. By this, the bonding agent 50 can be formed with a uniform thickness that is thinner than the bonding agent 40. By this, the uniformity of the in-plane temperature distribution of the ceramic plate 10 is secured. If the heater 12 were to directly contact the bottom face 11b of the recess 11, the uniformity of the temperature distribution of the ceramic plate 10 would worsen because the heat from the heater 12 would transfer to the ceramic plate 10 without going through the bonding agent 50. Further, extra stress would be placed on the ceramic plate 10 due to the thermal contraction of the heater 12. In other words, the bonding agent 50 also functions as a buffering agent.

Next, a more detailed description will be given of a configuration of the recess 11 provided in the ceramic plate 10 and of the heater 12 provided in the recess 11.

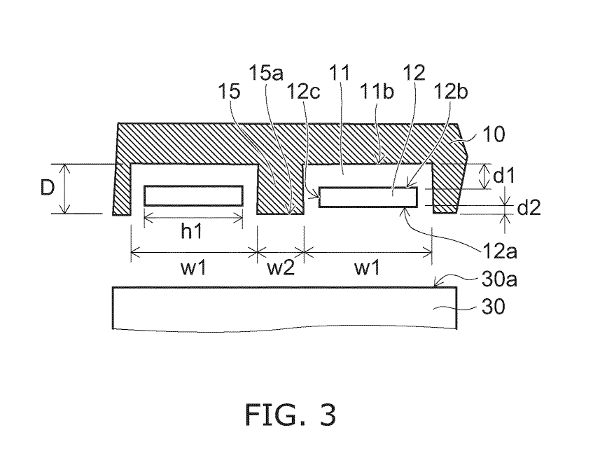

FIG. 3 is a cross-sectional schematic view of a relevant part of the recess and the heater.

In the cross-section of the heater 12, the major surface 12b that is substantially parallel to the major surface of the ceramic plate 10 is longer than the side surface 12c that is substantially perpendicular to the major surface of the ceramic plate 10. In other words, the cross-section of the heater 12 is a rectangular shape. In this embodiment, relationships W1>D, W1>W2, and d1>d2 are satisfied when W1 is the width of the recess 11, D is the depth of the recess 11, W2 is the width of the protrusion 15 between recesses 11, d1 is the distance between the bottom face 11b of the recess 11 and the major surface 12b of the heater 12 of the bottom face 11b side, and d2 is the distance of the difference between the height of the top surface 15a of the protrusion 15 from the bottom face 11b of the recess 11 and the height of the major surface 12a of the temperature regulating plate 30 side of the heater 12 from the bottom face 11b of the recess 11.

Satisfying the above relationships secures the uniformity of the in-plane temperature distribution of the ceramic plate 10. In addition, rapid heating and cooling of the ceramic plate 10 becomes possible.

For example, a cross section of the heater 12 is a rectangular shape, and the long side (major surface 12b) of the cross section is substantially parallel to the major surface of the ceramic plate 10. By this, the heat from the heater 12 can be uniformly and rapidly conducted to the ceramic plate 10. As a result, the processing target substrate placed on the ceramic plate 10 can be uniformly and rapidly heated.

Further, satisfying relationships between W1>D, W1>W2, and d1>d2 maintains the uniformity of the in-plane temperature distribution of the ceramic plate and enables rapid heating and cooling of the ceramic plate.

If W1<D, then the protrusion 15 would be longer thus increasing the thermal resistance of the protrusion 15 of the ceramic plate 10. Therefore, the in-plane temperature distribution of the ceramic plate 10 worsens. Therefore, it is preferable that W1>D.

Further, if W1<W2, then the in-plane density of the heater 12 drops. Therefore, the in-plane temperature distribution of the ceramic plate 10 worsens. Therefore, it is preferable that d1>d2.

Further, if d1<d2, then the heater 12 is closer to the ceramic plate 10 side than when d1>d2. Therefore, the ceramic plate 10 is susceptible to the effects of the rapid expansion and contraction of the heater 12. For example, a crack may be generated in the ceramic plate 10 by the stress applied to the ceramic plate 10 due to the expansion and contraction of the heater 12. Further, the in-plane temperature of the ceramic plate 10 may also be susceptible to the effect of the pattern shape of the heater 12, in which case, uniformity may drop. Therefore, it is preferable that d1>d2.

Further, in this embodiment, d2≧10 μm. If d2≧10 μm, the heater 12 is not susceptible to the pressure from the spherical filler 42 and crack generation in the ceramic plate can be suppressed. Further, when a variation in the flatness and thickness of the major surface of the heater 12 is not more than 10 μm, and if d2≧10 μm, the variation in the flatness and thickness of the heater 12 can be absorbed (mitigated) by the bonding agent 40.

For example, Table 3 describes the existence of crack generation in the ceramic plate 10 when changing d2. When the value of d2 is negative, it means that the major surface 12a of the temperature regulating plate 30 side of the heater 12 is protruding to the temperature regulating plate 30 side more than the top surface 15a of the protrusion 15. Further, when the value of d2 is positive, it means that the major surface 12a of the temperature regulating plate 30 side of the heater 12 is drawn in to the ceramic plate 10 side more than the top surface 15a of the protrusion 15. It is understood that although a crack is generated when d2 is −10 μm to 0 μm, a crack is not generated at 10 to 30 μm.

TABLE 3
Existence of crack generation

| | Spherical filler | | | |
|---|---|---|---|---|
| | diameter | Distance d2 | Generation | |
| Test No. | (70 μm) | (μm) | of crack | Evaluation |
| 1 | 70 | −10 | Yes | X |
| 2 | 70 | 0 | Yes | X |
| 3 | 70 | 10 | No | ◯ |
| 4 | 70 | 20 | No | ◯ |

◯: good,
X: no good

In this embodiment, the width W1 of the recess 11 and the width W2 of the protrusion 15 between the recesses 11 satisfies the relationship of 20%≦W2/(W1+W2)≦45%.

When W2/(W1+W2) is less than 20%, the area of the top surface 15a of the protrusion 15 is reduced by the increase in the area of the heater 12. By this, the number of spherical filler 42 that contacts the top surface 15a of the protrusion 15 is reduced, and controlling the thickness of the bonding agent 40 according to the average diameter of the spherical filler 42 becomes difficult. For example, when W2/(W1+W2) is less than 20%, the bonding agent 40 may become thinner in local areas.

When W2/(W1+W2) is greater than 45%, the in-plane density of the heater 12 is lowered and the uniformity of the in-plane temperature distribution of the ceramic plate 10 drops.

If the relationship of 20%≦W2/(W1+W2)≦45% is satisfied, the thickness of the bonding agent 40 can be appropriately controlled by the average diameter of the spherical filler 42 such that the in-plane temperature distribution of the ceramic plate 10 is uniform.

For example, Table 4 shows the thickness variation in the bonding agent 40 and the uniformity of the in-plane temperature when changing W1 and W2.

TABLE 4
Relationship of groove width and projecting
portion width of protrusion

| | | | | | Temperature | |
|---|---|---|---|---|---|---|
| | | | | | uniformity | |
| Test | W1 | W2 | W2/(W1 + | Thickness | at rapid | |
| No. | (mm) | (mm) | W2) (%) | variation | heating | Evaluation |
| 1 | 2.6 | 0.5 | 16.1 | x | ∘ | x |
| 2 | 2.6 | 1.0 | 27.8 | ∘ | ∘ | ∘ |
| 3 | 2.6 | 2.6 | 50.0 | ∘ | x | x |

∘: good, x: no good

In this test, W1 is 2.6 mm and the widths W2 of the protrusion 15 are 0.5 mm, 1.0 mm, and 2.6 mm. When the value of W2/(W1+W2) is 16.1%, the uniformity of the in-plane temperature is favorable, however the thickness variation of the bonding agent 40 is unfavorable. Conversely, when at 50.0%, the thickness variation of the bonding agent 40 is favorable while the uniformity of the in-plane temperature is unfavorable. Therefore, it is preferred that 20%≦W2/(W1+W2)≦45%.

Further, the arithmetic mean roughness (Ra) of the bottom face 11b of the recess 11 is greater than the arithmetic mean roughness (Ra) of the top surface 15a of the protrusion 15, and the maximum height roughness (Rz) of the bottom face 11b of the recess 11 is greater than the maximum height roughness (Rz) of the top surface 15a of the protrusion 15. The definition of top surface roughness complies with JIS B0601:2001.

By having the arithmetic mean roughness and the maximum height roughness of the bottom face 11b of the recess 11 to be greater than the arithmetic mean roughness and the maximum height roughness of the top surface 15a of the protrusion 15, promotes an anchor effect thereby improving the adhesion performance of the bonding agent 50. When the adhesive force of the bonding agent 50 is weak, the heater 12 may peel off from the ceramic plate 10. Further, the heater 12 rapidly expands and contracts according to the heating and cooling. Therefore, if the bonding agent 50 having a high adhesive force is between the bottom face 11b of the recess 11 and the heater 12, peeling of the heater 12 can be suppressed.

For example, Table 5 shows the relationship of the adhesion holding possibility of the heater 12 for Ra and Rz.

TABLE 5
Adhesion holding possibility

| | Bottom | Bottom | Protrusion | Protrusion | Adhesion | |
|---|---|---|---|---|---|---|
| | face of | face of | top | top | holding | |
| Test | recess | recess | surface | surface | of | Eval- |
| No. | Ra(μm) | Rz (μm) | Ra (μm) | Rz (μm) | heater | uation |
| 1 | 0.6-0.84 | 4.8-5.5 | 0.28-0.36 | 2.4-2.8 | ∘ | ∘ |
| 2 | 1.1-1.4 | 7.7-8.6 | 0.38-0.55 | 4.6-4.8 | ∘ | ∘ |
| 3 | 0.38-0.47 | 2.8-4.8 | 0.38-0.47 | 2.8-4.8 | x | x |

∘: good, x: no good

From Table 5, if the arithmetic mean roughness Ra of the bottom face 11b of the recess 11 is regulated to be not less than 0.5 μm and not more than 1.5 μm, and the maximum height roughness Rz of the bottom face 11b of the recess 11 is regulated to be not less than 4.0 μm and not more than 9.0 μm, then the adhesion holding force of the heater 12 is favorable. Further, if the arithmetic mean roughness Ra of the top surface 15a of the protrusion 15 is regulated to be not less than 0.2 μm and not more than 0.6 μm, and the maximum height roughness Rz of the top surface 15a of the protrusion 15 is regulated to be not less than 1.6 μm and not more than 5.0 μm, then the adhesion holding force of the heater 12 is favorable.

The corner of the recess 11 is implemented by an R process, and the R processing size is not more than three times the depth D of the recess 11. When the width of the heater 12 is the width h1, the width W1 is not less than “h1+0.3 mm” and not more than “h1+0.9 mm”. If the width W1 and h1 satisfy the relationship of (h1+0.3 mm)≦W1≦(h1+0.9 mm), then the heater 12 is securely fixed within the recess 11 and can be precisely positioned without the heater 12 rising up from the recess 11.

Further, when the heater 12 is bonded by the bonding agent 50 inside the recess 11, the clearance between the recess 11 and the heater 12 is a dimension and shape that can be eliminated by the amorphous filler 53 contained in the bonding agent 50. Because the R process is executed at the corner of the recess 11, crack generation originating at the corner can be prevented.

For example, in Table 6, a relationship is shown between the width h1 and clearance of the heater 12 to the existence of heater rise up generation and heater positioning within the groove.

TABLE 6
Heater positioning result

| | | | | Existence | | |
|---|---|---|---|---|---|---|
| | Heater | Clearlance | | of heater | | |
| Test | width | One | Both | rise up | Heater | |
| No. | (mm) | side | sides | generation | positioning | Evaluation |
| 1 | 2.0 | 0.1 | 0.2 | x | ∘ | x |
| 2 | 2.0 | 0.2 | 0.4 | ∘ | ∘ | ∘ |
| 3 | 2.0 | 0.4 | 0.8 | ∘ | ∘ | ∘ |
| 4 | 2.0 | 0.5 | 1.0 | ∘ | x | x |

∘: good, x: no good

The radius of the R process of the corner of the recess 11 in this case is 0.27 mm, and the width h1 of the heater 12 is 2 mm. If the width W1 of the recess 11 is not less than h1+0.3 mm and not more than h1+0.9 mm when the width of the heater 12 is the width h1, then the heater 12 can be precisely positioned within the recess 11 without the heater 12 rising up from the bottom face 11b of the recess 11.

Next, because the blending quantity within the bonding agent 40 of the spherical filler 42 has been verified, a description will follow hereafter. 80 wt % amorphous filler 43 is contained in advance in the bonding agent 40.

Table 7 shows the blending quantity test results of the spherical filler 42. In this test, verification was performed of the volume concentration that is possible for blending and dispersing the spherical filler 42 within the bonding agent 40 in which the amorphous filler 43 is contained.

First, when the volume concentration of the spherical filler 42 is not more than 0.020 vol %, the thickness of the bonding agent 40 is thinner, and cracks were generated in the spherical filler 42 or the ceramic plate 10. The cause of this is presumed to be due to a localized concentration of press pressure at the time of hot press curing on the spherical filler 42 and on the ceramic plate 10 that abuts the spherical filler 42. Conversely, when the volume concentration of the spherical filler 42 is greater than 0.020 vol %, dispersion within the bonding agent 40 of the spherical filler 42 is favorable. In other words, the spherical filler 42 is spread evenly within the bonding agent 40, and thus, applying localized pressure to the ceramic plate 10 by the amorphous filler 43 is difficult. Therefore, crack generation in the ceramic plate 10 is suppressed.

Further, it was discovered that when the volume concentration of the spherical filler 42 is not less than 46.385 vol %, the spherical filler 42 is not sufficiently dispersed within the bonding agent 40. As long as the volume concentration (vol %) of the spherical filler 42 is less than 42.0 vol %, dispersion of the spherical filler 42 will be uniform within the bonding agent 40 in which the amorphous filler 43 is contained.

In this manner, it is preferred that the volume concentration of the spherical filler 42 is greater than 0.025 vol % but less than 42.0 vol % relative to the bonding agent 40 in which the amorphous filler 43 is contained.

TABLE 7
Blending quantity test results of spherical filler

| | Spherical | Adhesion | |
|---|---|---|---|
| Spherical | filler ratio | holding | |
| filler type | vol % | possibility | Remarks |
| glass | 0.008% | X | Large adhesion layer thickness = |
| | | | Lack of pressure at press |
| glass | 0.016% | X | Large adhesion layer thickness = |
| | | | Lack of pressure at press |
| glass | 0.020% | X | Partial lack of adhesion layer |
| | | | thickness |
| glass | 0.030% | ◯ | |
| glass | 0.040% | ◯ | |
| glass | 0.099% | ◯ | |
| glass | 0.199% | ◯ | |
| glass | 0.398% | ◯ | |
| glass | 0.586% | ◯ | |
| glass | 1.992% | ◯ | |
| glass | 7.116% | ◯ | Uniform adhesion layer thickness |
| glass | 34.627% | ◯ | Uniform adhesion layer thickness |
| glass | 41.300% | ◯ | Uniform adhesion layer thickness |
| glass | 46.385% | X | Impossible stirring of adhesive |
| | | | and filler |
| glass (2) | 0.178% | ◯ | |
| glass (2) | 0.357% | ◯ | |
| glass (2) | 0.722% | ◯ | |
| alumina | 0.026% | ◯ | |
| alumina | 0.052% | ◯ | |
| alumina | 0.103% | ◯ | |

Compressive strength of glass: 832 Mpa
Compressive strength of glass (2): 466 Mpa
Compressive strength of alumina: 3200 Mpa
◯: adhesion possible,
X: adhesion impossible

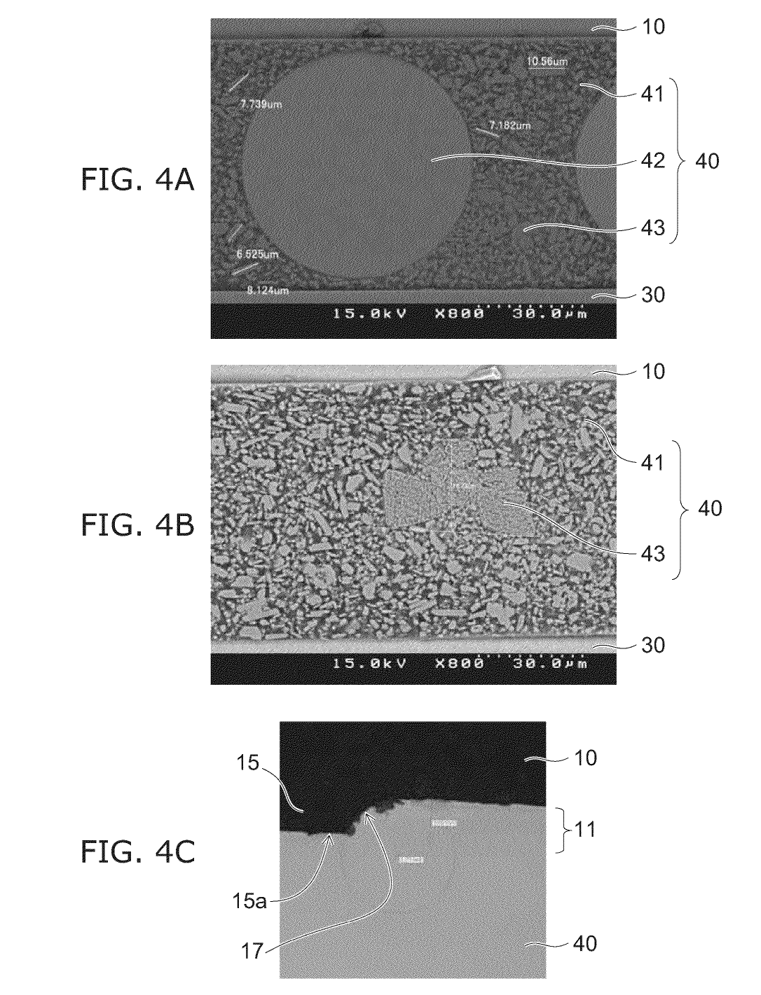

FIGS. 4A to 4C are cross-sectional SEM images of the bonding agent, and FIG. 4A is a cross-sectional SEM image of the bonding agent in which the spherical filler and the amorphous filler are blended and dispersed, FIG. 4B is a cross-sectional SEM image of the bonding agent in which the amorphous filler is blended and dispersed, and FIG. 4C is a cross-sectional SEM image of the recess. The field of view of the cross-sectional SEM image is 800× magnification.

In the bonding agent 40 shown in FIG. 4A, the spherical filler 42 and the amorphous filler 43 are blended and dispersed within the major agent 41. The ceramic plate 10 and the temperature regulating plate 30 can be observed above and below the bonding agent 40. In this SEM image, the spherical filler 42 does not reach the lower surface of the ceramic plate 10 and the upper surface of the temperature regulating plate 30, and this is because the spherical filler 42 is cut at the front side (with a deep side) from the maximum diameter. The diameter of the spherical filler 42 is approximately 70 μm.

In the bonding agent 40 shown in FIG. 4B, the spherical filler 42 is not dispersed. In other words, only the major agent 41 and the amorphous filler 43 can be observed between the ceramic plate 10 and the temperature regulating plate 30. The results of the maximum value of the sure diameter of the amorphous filler 43 from the cross-sectional SEM image are shown in Table 8.

TABLE 8
Maximum value of minor axis of amorphous filler

| | Maximum value of |
|---|---|
| | minor axis of |
| | amorphous filler |
| No. | (μm) |
| 1 | 10.56 |
| 2 | 12.26 |
| 3 | 11.95 |
| 4 | 10.09 |
| 5 | 15.87 |
| 6 | 13.05 |
| 7 | 10.40 |
| 8 | 11.07 |
| 9 | 16.20 |
| 10 | 11.58 |
| 11 | 13.20 |
| 12 | 26.73 |
| 13 | 15.75 |
| 14 | 9.73 |
| 15 | 15.42 |
| 16 | 11.27 |

From Table 8, the maximum values of the minor axis of the amorphous filler 43 are varied within a range from 9.73 μm to 26.73 μm. Because the average diameter of the spherical filler 42 is 70 μm, it is understood that the average diameter of the spherical filler is greater than all the maximum values of the minor axes of the amorphous filler 43.

Further, it can be understood from the cross section of the recess 11 shown in FIG. 4C that the depth of the recess 11 is 100 μm, and that the radius of the R process of the corner 17 is approximately 0.27 mm.

Note that FIG. 5 is a diagram for describing the minor axis of the amorphous filler.

The minor axis of the amorphous filler 43 is the length of the short direction that is orthogonal to the longitudinal direction (arrow C) of the amorphous filler 43. For example, this corresponds to d1, d2, d3, and the like in the drawing. The maximum values of the minor axis are the largest minor axis values from among the plurality of all the minor axes of the amorphous filler 43.

FIG. 6 is a cross-sectional schematic view of a relevant part according to a variation of an electrostatic chuck. This drawing corresponds to FIG. 1B.

In the electrostatic chuck 2, the ceramic plates 70 and 71 are Coulombic type raw material in which the volume resistivity (20° C.) is not less than 10¹⁴Ω·cm. Because the ceramic plates 70 and 71 are a Coulombic type raw material, the adsorptive power of the processing target substrate and the desorption responsiveness of the processing target substrate are stable even when the temperature during treatment of the processing target substrate changes. Further, the diameter thereof is 300 mm, and the thickness is between 1 to 4 mm.

In the electrostatic chuck 2, and electrode 72 is interposed between the ceramic plates 70 and 71. The electrode 72 is provided so as to follow the major surface of the ceramic plates 70 and 71. When a voltage is applied to the electrode 72, the ceramic plates 70 and 71 take on static electricity. By this, the processing target substrate undertakes electrostatic adsorption on the ceramic plate 70.

Such other configuration is in the same manner as with the electrostatic chuck 1. In other words, a similar effect to the electrostatic chuck 1 can be obtained also with the electrostatic chuck 2.

In addition, in this embodiment, the thermal conductivity of the spherical filler 42 and the amorphous filler 43 is higher than the thermal conductivity of the major agent 41 of the bonding agent 40

Because the thermal conductivity of the spherical filler 42 and the amorphous filler 43 is higher than the major agent 41 of the bonding agent 40, the thermal conductivity of the bonding agent 40 rises more than the bonding agent of the major agent elemental substance and thus improves cooling performance.

The material of the spherical filler 42 and the material of the amorphous filler 43 are different.

The purpose of adding the spherical filler 42 to the first bonding agent 40 is to provide uniformity in the thickness of the bonding agent 40 and to disperse the stress applied to the ceramic plate 10. Meanwhile, the purpose of adding the amorphous filler 43 to the bonding agent 40 is to increase the thermal conductivity of the bonding agent 40 and to provide uniformity in the thermal conductivity. In this manner, selecting a more favored material that matches these purposes allows a better performance to be obtained.

The thermal conductivity of the spherical filler 42 is lower than the thermal conductivity of the amorphous filler 43.

For example, when the spherical filler 42 contacts the protrusion 15 of the ceramic plate 10, the difference between the thermal conductivity of this contact portion is less than that of the other portions. By this, uniformity can be provided in the in-plane temperature distribution of the ceramic plate 10.

The thermal conductivities of the spherical filler 52 contained in the bonding agent 50 and the amorphous filler 53 contained in the bonding agent 50 are higher than the thermal conductivity of the major agent 51 of the bonding agent 50.

Because the thermal conductivities of the spherical filler 52 and the amorphous filler 53 are higher than the major agent 51 of the bonding agent 50, the thermal conductivity of the bonding agent 50 rises more than the bonding agent of the major agent elemental substance and thus improves cooling performance.

The material of the spherical filler 52 and the material of the amorphous filler 53 are different.

The purpose of adding the spherical filler 52 to the bonding agent 50 is to provide uniformity in the thickness of the bonding agent 50 and to disperse the stress applied to the ceramic plate 10. Meanwhile, the purpose of adding the amorphous filler 53 to the bonding agent 50 is to increase the thermal conductivity of the bonding agent 50 and to provide uniformity in the thermal conductivity. In this manner, selecting a more favored material that matches these purposes allows a better performance to be obtained.

The thermal conductivity of the spherical filler 52 is lower than the thermal conductivity of the amorphous filler 53. For example, when the spherical filler 52 contacts the bottom face 11b of the recess 11 provided on the ceramic plate 10, the difference between the thermal conductivity of this contact portion is less than that of the other portions. By this, uniformity can be provided in the in-plane temperature distribution of the ceramic plate 10.

Further, the thermal conductivity of the spherical filler 52 is less than or equal to the thermal conductivity of a blended material of amorphous filler 53 and the major agent 51.

By making the thermal conductivity of the spherical filler 52 to be less than or equal to the thermal conductivity of the blended material of the amorphous filler 53 and the major agent 51, the thermal conductivity within the bonding agent 50 becomes further constant, and the generation of a singular point of temperature known as a hot spot or a cold spot within the bonding agent 50 can be suppressed at the time of thermal conduction.

The thermal conductivity of the spherical filler 52 is in a range from 0.4 times to 1.0 times the thermal conductivity of a blended material of the amorphous filler 53 and the major agent 51.

Making the thermal conductivity of the spherical filler 52 to be in a range not less than 0.4 times and not more than 1.0 times the thermal conductivity of the blended material of the amorphous filler 53 and the major agent 51, enables the thermal conductivity within the bonding agent 50 to be more uniform. As a result, the generation of a singular point of temperature known as a hot spot or a cold spot within the bonding agent 50 can be suppressed at the time of thermal conduction.

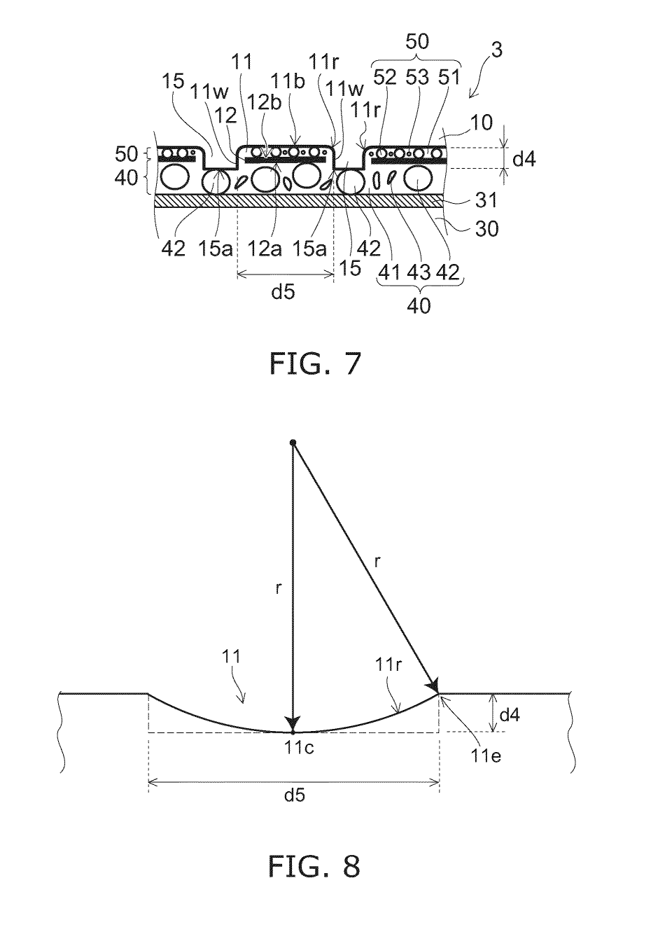

FIG. 7 is an essential part cross-sectional schematic view according to another variation of the electrostatic chuck.

In the electrostatic chuck 3, a tapered portion 11r in which the depth of the recess 11 becoming gradually shallower towards an edge of the recess 11 is provided on the edge region of the recess 11.

An adhesive is applied to the inner part of the recess 11 prior to adhering the heater 12 to the inner part of the recess 11. When the tapered portion 11r in which the depth of the recess 11 becoming gradually shallower towards the edge of the recess 11 is provided on the edge region of the recess 11, air bubbles are difficult to occur in the tapered portion 11r at the time of applying the adhesive. Even if air bubbles were to occur, as long as the tapered portion 11r is provided, the air bubbles can be easily removed thereafter at the time of press bonding.

Further, when adhering the heater 12 to the inner part of the recess 11, press bonding causes the large shaped first amorphous filler 42 to flow out from within the recess 11. At this time, providing the tapered portion 11r on the edge region of the recess 11 allows easy outflow of the first amorphous filler 42 having a large shape. As a result, the distance between the heater 12 and the ceramic plate 10 can be more uniformly controlled depending on the average grain size of the first spherical filler 42.

In addition, when the tapered portion 11r is provided on the edge region of the recess 11, a pressure gradient is generated in the recess 11 when the heater 12 is pressed bonded, and as a result, there is increased precision of the positioning (centering) relative to the recess 11 of the heater 12.

For example, in FIG. 7, a continuously curved surface is shown as one example of the tapered portion 11r. In the inner part of the recess 11, the side ace 11w and the bottom face 11b meet in a continuous curved surface. This type of continuous curved surface can be formed by, for example, a sandblast. As one example, when the shape of this curved surface approximates an R shape, it is preferable that the size of the R (R size) is not less than 0.5 times the depth d4 of the recess 11 and not more than 0.5 times the width d5 of the recess 11.

With the R size less than 0.5 times d4, the cross point of the side surface 11w and the bottom face 11b of the recess 11 form a shape close to a corner. Therefore, air bubbles in the recess 11 are easily generated at the time of applying adhesive, and the generated air bubbles easily remain in the recess 11. In addition, a singular point in which an electric field is generated in between the electrode 13 and the recess 11 is easily generated, and breakdown of a breakdown voltage may also occur.

On the other hand, when the R size is larger than 0.5 times the width d5 of the recess 11, the curved surface may curve into the bottom of the heater 12 and thus no longer maintain a constant distance between the heater 12 and the bottom face 11b of the recess 11. Further, the precision of positioning the heater 12 within the recess 11 may drop.

Further, the R size may be restricted to the size shown in FIG. 6 below.

FIG. 8 is a cross-sectional schematic view of the recess periphery of an electrostatic chuck.

When the curved surface of the tapered portion 11r is assumed to be an arc of a radius r, the radius r of the arc that contacts the lower end edge 11e of the recess 11 and the center 11c of the bottom face 11b of the recess 11 becomes the upper limit of the R size.

Because the upper limit of the radius r is expressed by (½)·d4+d5²/(8·d4), the upper limit of the R size) may be (½)·d4+d5²/(8·d4).

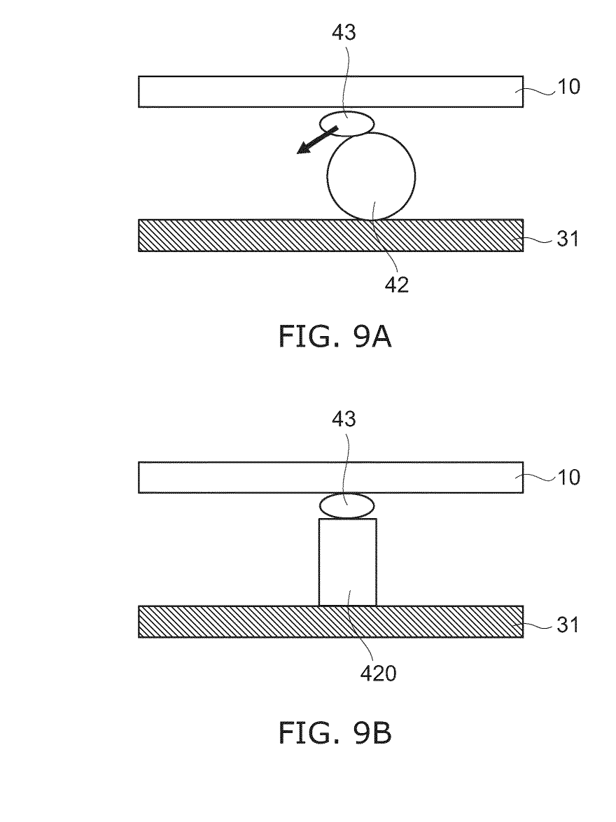

Further, FIGS. 9A and 9B are diagrams for describing one example of an effect of the electrostatic chuck. FIG. 9A shows a cross-sectional schematic view of the electrostatic chuck 1, and FIG. 9B shows a comparative example.

Because the spherical filler 42 is spherically shaped, the amorphous filler 43 slides more easily on account of the curved surface of the spherical filler 42 when the spherical filler 42 is being pressed on the ceramic plate 10 side even if large amorphous filler 43 exists between the ceramic plate 10 and the spherical filler 42. Therefore, in the electrostatic chuck 1, the amorphous filler 43 becomes difficult to remain in between the spherical filler 42 and the ceramic plate 10.

In contrast to this, in a comparative example, because a cylindrical filler 420 is used, the amorphous filler 43 is easily interposed between the cylindrical filler 42 and the ceramic plate 10. Therefore, in a comparative example, the amorphous filler 43 easily remains between the cylindrical filler 420 and the ceramic plate 10. Therefore, as described in this embodiment, use of the spherical filler 42 is preferred.

The invention has been described with reference to the embodiments. However, the invention is not limited to these descriptions. Those skilled in the art can suitably modify the above embodiments by design change, and such modifications are also encompassed within the scope of the invention as long as they include the feature of the invention. For example, the shape, dimension, materials and disposal of components are not limited to those illustrated, and can be suitably modified.

Components of the embodiments described above can be combined and multiple as long as technically possible, and such combinations can be encompassed within the scope of the invention as long as they include the feature of the invention.

### INDUSTRIAL APPLICABILITY

Used as an electrostatic chuck for clamping a processing target substrate.

### REFERENCE SIGNS LIST

1, 2 electrostatic chuck
10 ceramic plate
11 recess 12 heater
12a, 12b major surface
12c side surface
13 electrode
15 protrusion
15a top surface
16 crack
17 corner
30 temperature regulating plate
30a major surface
30t medium path
31 insulating film
40, 50 bonding agent
41, 51 major agent
42, 52 spherical filler
43, 53 amorphous filler
70, 71 ceramic plate
72 electrode
A, B, C arrow

1. An electrostatic chuck, comprising:
a ceramic plate provided with recesses on a major surface and provided with an electrode in an inner part of the ceramic plate;
a temperature regulating plate bonded to the major surface of the ceramic plate;
a first bonding agent provided between the ceramic plate and the temperature regulating plate; and
a heater provided in the each of the recesses of the ceramic plate,
the first bonding agent having a first major agent including an organic material, a first amorphous filler including an inorganic material, and a first spherical filler including an inorganic material,
the first amorphous filler and the first spherical filler being dispersion-compounded into the first major agent,
the first major agent, the first amorphous filler, and the first spherical filler being made of an electrically insulating material,
an average diameter of the first spherical filler being greater than a maximum value of a minor axis of the first amorphous filler,
a thickness of the first bonding agent being greater than or equal to the average diameter of the first spherical filler,
a width of the each of the recesses being greater than a width of the heater, and a depth of the each of the recesses being greater than a thickness of the heater,
the heater being adhered within the each of the recesses by a second bonding agent, and
a first distance between a major surface of the heater on the side of the temperature regulating plate and a major surface of the temperature regulating plate being greater than a second distance between the major surface between the recesses of the ceramic plate and the major surface of the temperature regulating plate.

2. The electrostatic chuck according to claim 1, wherein the average diameter of the first spherical fillers is 10 μm more than or equal to the maximum value of the minor axis of the amorphous filler.

3. The electrostatic chuck according to claim 1, wherein a volume concentration (vol %) of the first spherical filler is more than 0.025 vol % and less than 42.0 vol % relative to a volume of the first bonding agent in which the first amorphous filler is contained.

4. The electrostatic chuck according to claim 1, wherein a material for the first major agent of the first bonding agent and a material for a second major agent of the second bonding agent is one of a silicon resin, an epoxy resin, or a fluororesin.

5. The electrostatic chuck according to claim 1, wherein a thermal conductivity of the first spherical filler and a thermal conductivity of the first amorphous filler are higher than a thermal conductivity of the first major agent of the first bonding agent.

6. The electrostatic chuck according to claim 1, wherein a material of the first spherical filler and a material of the first amorphous filler are different.

7. The electrostatic chuck according to claim 5, wherein the thermal conductivity of the first spherical filler is lower than the thermal conductivity of the first amorphous filler.

8. The electrostatic chuck according to claim 7, wherein the thermal conductivity of the first spherical filler is less than or equal to a thermal conductivity of a blended material of the first amorphous filler and the first major agent.

9. The electrostatic chuck according to claim 8, wherein the thermal conductivity of the first spherical filler is in a range not less than 0.4 times and not more than 1.0 times the thermal conductivity of the blended material of the first amorphous filler and the first major agent.

10. The electrostatic chuck according to claim 1, wherein a Vickers hardness of the first spherical filler is less than a Vickers hardness of the ceramic plate.

11. The electrostatic chuck according to claim 1, wherein relationships W1>D, W1>W2, and d1>d2 are satisfied, in a cross-section of the heater in which a surface that is substantially parallel to the major surface of the ceramic plate is longer than a surface that is substantially perpendicular to the major surface of the ceramic plate, when
W1 is a width of the each of the recesses,
D is a depth of the each of the recesses,
W2 is a width of the major surface between the recesses,
d1 is a distance between a bottom face of the each of the recesses and a major surface of the heater, the major surface facing the bottom face, and
d2 is a distance of a difference between a height of the major surface of the ceramic plate from the bottom face of the each of the recesses and a height of the major surface of the heater from the bottom face of the each of the recesses, the major surface of the heater facing the temperature regulating plate.

12. The electrostatic chuck according to claim 11, wherein a tapered portion with a depth gradually shallower toward an end of the each of the recesses is provided on an edge region of the each of the recesses.

13. The electrostatic chuck according to claim 1, wherein the second bonding agent has a second major agent including an organic material, a second amorphous filler including an inorganic material, and a second spherical filler including an inorganic material,
the second amorphous filler and the second spherical filler are dispersion-compounded into the second major agent,
the second major agent, the second amorphous filler, and the second spherical filler are made of an electrically insulating material,
an average diameter of the second spherical filler is greater than a maximum value of a minor axis of the second amorphous filler,
a thickness of the second bonding agent is greater than or equal to the average diameter of the second spherical filler, and
the average diameter of the second spherical filler is less than or equal to the average diameter of the first spherical filler.

14. The electrostatic chuck according to claim 13, wherein a thermal conductivity of the second spherical filler contained in the second bonding agent and a thermal conductivity of the second amorphous filler contained in the second bonding agent are higher than a thermal conductivity of the second major agent of the second bonding agent.

15. The electrostatic chuck according to claim 13, wherein a material of the second spherical filler and a material of the second amorphous filler are different.

16. The electrostatic chuck according to claim 14, wherein the thermal conductivity of the second spherical filler is lower than the thermal conductivity of the second amorphous filler.

17. The electrostatic chuck according to claim 16, wherein the thermal conductivity of the second spherical filler is less than or equal to a thermal conductivity of a blended material of the second amorphous filler and the second major agent.

18. The electrostatic chuck according to claim 17, wherein the thermal conductivity of the second spherical filler is in a range not less than 0.4 times and not more than 1.0 times the thermal conductivity of the blended material of the second amorphous filler and the second major agent.

19. The electrostatic chuck according to claim 13, wherein a width W1 of the each of the recesses and a width W2 of the major surface between the recesses satisfies a relationship 20%≦W2/(W1+W2)≦45%.

20. The electrostatic chuck according to claim 13, wherein an arithmetic mean roughness (Ra) of the bottom face of the recesses is greater than an arithmetic mean roughness (Ra) of the major surface of the ceramic plate, and a maximum height roughness (Rz) of the bottom face of the recesses is greater than a maximum height roughness (Rz) of the major surface of the ceramic plate.

21. The electrostatic chuck according to claim 13, wherein a distance d2 of the difference between a height of the major surface of the ceramic plate from the bottom face of the each of the recesses and a height of the major surface of the heater from the bottom face of the each of the recesses, the major surface of the heater facing the temperature regulating plate, is such that d2≧10 μm.

22. The electrostatic chuck according to claim 13, wherein an insulator film is formed on the major surface of the temperature regulating plate.
